(19) United States
(12) Patent Application Publication
(10) Pub. No.: US 2026/0164937 A1
(43) Pub. Date: Jun. 11, 2026

(54) Display Substrate and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Yanwei LU, Beijing (CN); Hongjun ZHOU, Beijing (CN); Fengli JI, Beijing (CN)

(21) Appl. No.: 18/705,603

(22) PCT Filed: Mar. 28, 2023
(86) PCT No.: PCT/CN2023/084487

§ 371 Date: Apr. 29, 2024

(51) Int. Cl. H10K 59/122

(52) U.S. Cl. CPC H10K 59/122

(57) ABSTRACT

A display substrate and a display apparatus. The display substrate comprises a plurality of sub-pixels and a pixel definition layer, wherein a plurality of pixel openings are formed in the pixel definition layer, and each sub-pixel comprises at least one pixel opening; and the plurality of sub-pixels comprise first sub-pixels (P1), second sub-pixels (P2) and third sub-pixels (P3), at least one first sub-pixel (P1) being adjacent to both the second sub-pixel (P2) and the third sub-pixel (P3), and the minimum distance from a pixel opening (61) of the at least one first sub-pixel (P1) to a pixel opening (62) of one adjacent second sub-pixel (P2) being different from the minimum distance between the pixel opening of the at least one first sub-pixel (P1) to a pixel opening (63) of one adjacent third sub-pixel (P3).

### CROSS-REFERENCE TO RELATED APPLICATION

The present application is a U.S. National Phase Entry of International Application No. PCT/CN2023/084487 having an international filing date of Mar. 28, 2023, the content of which is hereby incorporated by reference.

### TECHNICAL FIELD

The present disclosure relates to, but is not limited to, the field of display technologies, and particularly relates to a display substrate and a display apparatus.

### BACKGROUND

An organic light emitting diode (OLED for short) and a quantum dot light emitting diode (QLED for short) are active light emitting display devices and have advantages such as self-luminescence, wide viewing angle, high contrast ratio, low power consumption, very high response speed, lightness and thinness, flexibility, and low cost. With continuous development of display technologies, a flexible display apparatus (Flexible Display) in which an OLED or a QLED is used as a light emitting device and a thin film transistor (TFT for short) is used for signal control has become a mainstream product in the field of display at present.

### SUMMARY

The following is a summary of subject matter described herein in detail. The summary is not intended to limit the scope of protection of the claims.

In one aspect, the present disclosure provides a display substrate including multiple sub-pixels and a pixel definition layer, multiple pixel openings are formed in the pixel definition layer, and each sub-pixel includes at least one pixel opening.

The multiple sub-pixels include a first sub-pixel, a second sub-pixel, and a third sub-pixel, wherein at least one first sub-pixel is adjacent to a second sub-pixel and a third sub-pixel, and a closest distance between a pixel opening of the at least one first sub-pixel and a pixel opening of an adjacent second sub-pixel is different from a closest distance between the pixel opening of the at least one first sub-pixel and a pixel opening of an adjacent third sub-pixel.

In an exemplary implementation, the at least one first sub-pixel is at least adjacent to two second sub-pixels, and the at least one first sub-pixel is at least adjacent to two third sub-pixels, and a closest distance between the pixel opening of the at least one first sub-pixel and a pixel opening of another adjacent second sub-pixel is the same as a closest distance between the pixel opening of the at least one first sub-pixel and a pixel opening of another adjacent third sub-pixel.

In an exemplary implementation, one first sub-pixel, one second sub-pixel, and one third sub-pixel are sequentially arranged in a first direction, and a closest distance between a pixel opening of a first sub-pixel and a pixel opening of a second sub-pixel is different from a closest distance between the pixel opening of the second sub-pixel and a pixel opening of a third sub-pixel, and the first direction is one of a row direction or a column direction.

In an exemplary implementation, the at least one first sub-pixel is at least adjacent to two second sub-pixels, and closest distances between the pixel opening of the at least one first sub-pixel and pixel openings of the adjacent two second sub-pixels are different.

In an exemplary implementation, the at least one first sub-pixel is at least adjacent to two third sub-pixels, and closest distances between the pixel opening of the at least one first sub-pixel and pixel openings of the adjacent two third sub-pixels are different.

In an exemplary implementation, a closest distance from a pixel opening of a sub-pixel located in a same row as a pixel opening of the at least one first sub-pixel and adjacent to the at least one first sub-pixel to the pixel opening of the at least one first sub-pixel is different from a closest distance from a pixel opening of a sub-pixel located in a different row from the pixel opening of the at least one first sub-pixel and adjacent to the at least one first sub-pixel to the pixel opening of the at least one first sub-pixel.

In an exemplary implementation, the closest distance from the pixel opening of the sub-pixel located in the same row as the pixel opening of the at least one first sub-pixel and adjacent to the at least one first sub-pixel to the pixel opening of the at least one first sub-pixel is greater than the closest distance from the pixel opening of the sub-pixel located in the different row from the pixel opening of the at least one first sub-pixel and adjacent to the at least one first sub-pixel to the pixel opening of the at least one first sub-pixel.

In an exemplary implementation, opposite sides of pixel openings of at least a portion of sub-pixels and pixel openings of a portion of adjacent sub-pixels are parallel sides, and parts of pixel openings of the at least a portion of sub-pixels opposite to pixel openings of some other adjacent sub-pixels include an angle, a rounded angle, or a side with a side length less than 1/10 of a perimeter of a pixel opening of the sub-pixel.

In an exemplary implementation, the multiple sub-pixels include light emitting layers corresponding to pixel openings, wherein the first sub-pixel includes a first light emitting layer, the second sub-pixel includes a second light emitting layer, and the third sub-pixel includes a third light emitting layer;

a closest distance from at least one first light emitting layer to an adjacent second light emitting layer is different from a closest distance from the at least one first light emitting layer to an adjacent third light emitting layer.

In an exemplary implementation, light emitting layers of at least a portion of adjacent sub-pixels are spaced, and spacings between light emitting layers of different sub-pixels are different; or light emitting layers of at least a portion of adjacent sub-pixels are overlapped, and overlapping areas are different; or light emitting layers of a portion of adjacent sub-pixels are overlapped, and light emitting layers of another portion of adjacent sub-pixels are spaced.

In an exemplary implementation, a shape of light emitting layers in at least a portion of the sub-pixels is different from a shape of corresponding pixel openings.

In an exemplary implementation, the at least one first light emitting layer is at least adjacent to two second light emitting layers, and the at least one first light emitting layer is at least adjacent to two third light emitting layers, and a closest distance from the at least one first light emitting layer to another adjacent second light emitting layer is the same as a closest distance from the at least one first light emitting layer to another adjacent third light emitting layer.

In an exemplary implementation, one first light emitting layer, one second light emitting layer, and one third light emitting layer are sequentially arranged in a first direction, and a closest distance between a first light emitting layer and a second light emitting layer is different from a closest distance between the second light emitting layer and a third light emitting layer, and the first direction is one of a row direction or a column direction.

In an exemplary implementation, the at least one first light emitting layer is at least adjacent to two second light emitting layers, and closest distances between the at least one first light emitting layer and the adjacent two second light emitting layers are different.

In an exemplary implementation, the at least one first light emitting layer is at least adjacent to two third light emitting layers, and closest distances between the at least one first light emitting layer and the adjacent two third light emitting layers are different.

In an exemplary implementation, a closest distance from a light emitting layer located in a same row as and adjacent to the at least one first light emitting layer to the at least one first light emitting layer is different from a closest distance from a light emitting layer located in a different row from and adjacent to the at least one first light emitting layer to the at least one first light emitting layer.

In an exemplary implementation, the closest distance from the light emitting layer located in the same row as and adjacent to the at least one first light emitting layer to the at least one first light emitting layer is greater than the closest distance from the light emitting layer located in the different row from and adjacent to the at least one first light emitting layer to the at least one first light emitting layer.

In an exemplary implementation, the at least one first light emitting layer has a hexagonal shape, the hexagonal first light emitting layer includes a first edge and a second edge provided oppositely in a row direction, in the row direction the first edge of the first light emitting layer is adjacent to an adjacent third light emitting layer, and the second edge of the first light emitting layer is adjacent to an adjacent second light emitting layer, and a size of the second edge in a column direction is greater than or equal to a size of the first edge in the column direction.

In an exemplary implementation, at least one of the first edge and the second edge has a size of 4 microns to 9 microns in the column direction.

In an exemplary implementation, a rhombus in which the hexagonal first light emitting layer is located includes a first included angle and a second included angle which are oppositely provided in the row direction, in the row direction the first included angle is located on a side of the first edge away from the second edge, and the second included angle is located on a side of the second edge away from the first edge, and a distance between a vertex of the second included angle and the second edge is greater than or equal to a distance between a vertex of the first included angle and the first edge.

In an exemplary implementation, in the row direction, a closest distance between at least one edge of the first edge and the second edge and a vertex of an included angle adjacent to the edge is 3 microns to 6 microns.

In an exemplary implementation, the first sub-pixel is a sub-pixel for emitting red light, the second sub-pixel is a sub-pixel for emitting blue light, and the third sub-pixel is a sub-pixel for emitting green light.

In an exemplary implementation, the display substrate further includes a drive circuit layer provided on a base substrate, wherein the drive circuit layer includes multiple circuit units, the multiple sub-pixels include light emitting units and circuit units, a light emitting unit is provided on a side of the drive circuit layer away from the base substrate, the light emitting unit includes an anode and a light emitting layer; the light emitting layer is located on a side of the anode away from the drive circuit layer, a circuit unit at least includes a pixel drive circuit, the pixel driving circuit at least includes a storage capacitor and a compensation transistor, a first electrode of the compensation transistor is connected to a first plate of the storage capacitor through a first connection electrode; the anode of the light emitting unit is connected to the pixel drive circuit; in a row direction, an orthographic projection of an anode of at least one light emitting unit on the base substrate is not overlapped with an orthographic projection of a first connection electrode in a circuit unit, which is adjacent to the anode on at least a side, on the base substrate; in a column direction, an orthographic projection of an anode of at least one light emitting unit on the base substrate is at in least partially overlapped with an orthographic projection of a first connection electrode in a circuit unit, which is adjacent to the anode on at least a side, on the base substrate.

In an exemplary implementation, the multiple light emitting units form multiple sub-pixel rows, a sub-pixel row includes multiple light emitting units arranged sequentially in the row direction; the multiple circuit units form multiple unit rows, a unit row includes multiple circuit units arranged sequentially in the row direction, the multiple sub-pixel rows include multiple first sub-pixel rows and multiple second sub-pixel rows, the first sub-pixel rows and the second sub-pixel rows are alternately arranged in the column direction, positions of multiple pixel drive circuits in one unit row correspond to positions of multiple light emitting units in two adjacent sub-pixel rows; in the column direction, an orthographic projection of anodes of multiple light emitting units in the first sub-pixel row on the base substrate is at least partially overlapped with an orthographic projection of a first connection electrode in an adjacent unit row on the base substrate, and an orthographic projection of anodes of multiple light emitting units in the second sub-pixel row on the base substrate is at least partially overlapped with an orthographic projection of a first connection electrode in a corresponding unit row on the base substrate.

In an exemplary implementation, an anode of at least one light emitting unit located in the first sub-pixel row includes an anode main body part, an anode connection part, and an anode compensation part, the anode connection part is configured to be connected to the pixel drive circuit, and the anode compensation part is provided on a side of the anode connection part away from the anode main body part.

In an exemplary implementation, the first connection electrode includes an electrode main body part and an electrode compensation part, the electrode main body part includes a first end connected to a first plate of the storage capacitor and a second end connected to a first electrode of the compensation transistor, and the electrode compensation part is provided on a side of the first end away from the second end;

in at least one circuit unit, an orthographic projection of the anode compensation part on the base substrate is at least partially overlapped with an orthographic projection of the electrode compensation part of the first connection electrode on the base substrate; in at least one circuit unit, the orthographic projection of the anode compensation part on the base substrate is at least partially overlapped with an orthographic projection of the electrode main body part of the first connection electrode on the base substrate.

In an exemplary implementation, in at least one light emitting unit located in a first sub-pixel row, an orthographic projection of the anode main body part on the base substrate is not overlapped with an orthographic projection of the first connection electrode on the base substrate; in at least one light emitting unit located in a second sub-pixel row, an orthographic projection of an anode main body part on the base substrate is at least partially overlapped with an orthographic projection of a first connection electrode on the base substrate; in at least one light emitting unit located in a first sub-pixel row, an orthographic projection of the anode compensation part on the base substrate is at least partially overlapped with an orthographic projection of a first connection electrode in an adjacent unit row on the base substrate.

In an exemplary implementation, the anode further includes a protrusion part, the protrusion part is provided on a side of the anode main body part away from the anode connection part, and an orthographic projection of the protrusion part of at least one anode in at least one sub-pixel row on the base substrate is at least partially overlapped with orthographic projections of multiple first connection electrodes in a corresponding unit row on the base substrate, respectively.

In an exemplary implementation, the multiple sub-pixel columns include multiple first sub-pixel columns and multiple second sub-pixel columns, the first sub-pixel columns and the second sub-pixel columns are alternately arranged in the row direction, multiple light emitting units in a first sub-pixel column are located in a first sub-pixel row, and multiple light emitting units in a second sub-pixel column are located in a second sub-pixel row.

The storage capacitor includes a first plate and a second plate, the second plate is provided with an opening, positions of multiple light emitting units of a sub-pixel column correspond to positions of multiple circuit units of a unit column, the multiple unit columns include multiple first unit columns and multiple second unit columns, the first unit columns and the second unit columns are alternately arranged in the row direction, orthographic projections of anode compensation parts of multiple light emitting units in a first sub-pixel column on the base substrate are at least partially overlapped with orthographic projections of openings on second plates of multiple circuit units in a corresponding first unit column on the base substrate, respectively, and the orthographic projections of the anode compensation parts of the multiple light emitting units in the first sub-pixel column on the base substrate are at least partially overlapped with orthographic projections of first connection electrodes of the multiple circuit units in the corresponding first unit column on the base substrate, respectively.

In another aspect, the present disclosure further provides a display apparatus including the display substrate described in any one of the embodiments of the present disclosure.

Other aspects of the present disclosure may be comprehended after the drawings and the detailed descriptions are read and understood.

### BRIEF DESCRIPTION OF DRAWINGS

Accompany drawings are intended to provide further understanding of technical solution of the present disclosure, and form a part of the specification. The accompany drawings and embodiments of the present disclosure are adopted to explain the technical solution of the present disclosure, but do not form limitations on the technical solution of the present disclosure.

FIG. 1 is a schematic diagram of a structure of a display apparatus.

FIG. 2 is a schematic diagram of a planar structure of a display substrate.

FIG. 3 is a schematic diagram of a sectional structure of a display substrate.

FIG. 4 is a schematic diagram of an equivalent circuit of a pixel drive circuit.

FIG. 5 is a schematic diagram of an arrangement of a circuit unit according to an exemplary embodiment of the present disclosure.

FIG. 6 is a schematic diagram of an arrangement of a light emitting unit according to an exemplary embodiment of the present disclosure.

FIG. 7 is a schematic diagram of a structure of a display substrate according to an exemplary embodiment of the present disclosure.

FIG. 8 is a schematic diagram of a display substrate after a pattern of a semiconductor layer is formed according to the present disclosure.

FIG. 9A and FIG. 9B are schematic diagrams of a display substrate after a pattern of a first conductive layer is formed according to the present disclosure.

FIGS. 10A and 10B are schematic diagrams of a display substrate after a pattern of a second conductive layer is formed according to the present disclosure.

FIG. 11 is a schematic diagram of a display substrate after a pattern of a fourth insulation layer is formed according to the present disclosure.

FIG. 12A and FIG. 12B are schematic diagrams of a display substrate after a pattern of a third conductive layer is formed according to the present disclosure.

FIG. 13 is a schematic diagram of a display substrate after a pattern of a planarization layer is formed according to the present disclosure.

FIG. 14A and FIG. 14B are schematic diagrams of a display substrate after a pattern of an anode conductive layer is formed according to the present disclosure.

FIG. 14C to FIG. 14E are planar schematic diagrams of an anode according to the present disclosure.

FIG. 15A to FIG. 15D are schematic diagrams of a display substrate after a pattern of a pixel definition layer is formed according to the present disclosure.

FIG. 15E to FIG. 15H are schematic diagrams of a display substrate after a pattern of a light emitting layer is formed according to the present disclosure.

FIG. 15I is a planar schematic diagram of a first light emitting layer in a display substrate according to the present disclosure.

FIG. 15J is a planar schematic diagram of a first anode and a first light emitting layer in a display substrate according to the present disclosure.

FIG. 15K is a planar schematic diagram of a pixel opening of a first sub-pixel in a display substrate according to the present disclosure.

FIG. 15L is a planar schematic diagram of a first anode and a pixel opening of a first sub-pixel in a display substrate according to the present disclosure.

FIG. 16A to FIG. 16C are schematic diagrams of a structure of another display substrate according to an exemplary embodiment of the present disclosure.

FIG. 17A to FIG. 17C are schematic diagrams of a structure of yet another display substrate according to an exemplary embodiment of the present disclosure.

Reference signs are described as follows.

| | | |
|---|---|---|
| 11-first | 12-second | 13-third |
| active layer; | active layer; | active layer; |
| 14-fourth | 15-fifth | 16-sixth |
| active layer; | active layer; | active layer; |
| 17-seventh | 21-first scan | 22-second scan |
| active layer; | signal line; | signal line |
| 23-light emitting | 24-first | 31-initial |
| control signal line; | plate; | signal line; |
| 32-second | 33-plate | 34-shielding |
| plate; | connection line; | electrode; |
| 35-opening; | 40-storage | 41-first |
| | capacitor; | connection electrode; |
| 41-1-electrode | 41-2-electrode | 42-second |
| main body part; | compensation part; | connection electrode; |
| 43-third | 44-data | 45-first power |
| connection electrode; | signal line; | supply line; |
| 50-anode; | 50-1-anode main | 50-2-anode |
| | body part; | compensation part; |
| 51-first | 52-second | 53-third |
| anode; | anode; | anode; |
| 54-fourth | 55-fifth | 61-pixel opening of |
| anode; | anode; | a first sub-pixel; |
| 62-pixel opening of | 63-pixel opening of | 71-first |
| a second sub-pixel; | a third sub-pixel; | protrusion part; |
| 72-second | 73-third | 74-fourth |
| protrusion part; | protrusion part; | protrusion part; |
| 75-fifth | 76-sixth | 81-first anode |
| protrusion part; | protrusion part; | compensation part; |
| 82-second anode | 83-third anode | 91-first light |
| compensation part; | compensation part; | emitting layer; |
| 92-second light | 93-third light | 101-base |
| emitting layer; | emitting layer; | substrate; |
| 102-drive | 103-light emitting | 104-encapsulation |
| circuit layer; | structure layer; | structure layer. |

### DETAILED DESCRIPTION

To make the objectives, technical solutions, and advantages of the present disclosure clearer, the embodiments of the present disclosure will be described in detail below with reference to the accompany drawings. It is to be noted that implementations may be implemented in various forms. Those of ordinary skills in the art can easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, and the like in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, and the like indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the composition elements may be changed as appropriate according to a direction according to which each composition element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; the connection may be a mechanical connection or an electrical connection; the connection may be a direct connection, or an indirect connection through a middleware, or an internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of composition elements through an element with a certain electrical action. An “element with a certain electrical action” is not particularly limited as long as electrical signals between the connected composition elements may be sent and received. Examples of the “element with a certain electrical action” not only include an electrode and a wiring, but also include a switching element such as a transistor, a resistor, an inductor, a capacitor, other elements with various functions, and the like.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

Triangle, rectangle, trapezoid, pentagon, hexagon, and the like in this specification are not strictly defined, and they may be approximate triangle, rectangle, trapezoid, pentagon, hexagon, and the like. There may be some small deformations caused by tolerance, and there may be chamfer, arc edge, deformation, and the like.

In the present disclosure, “about” refers to that a boundary is not defined so strictly and numerical values within a range of process and measurement errors are allowed.

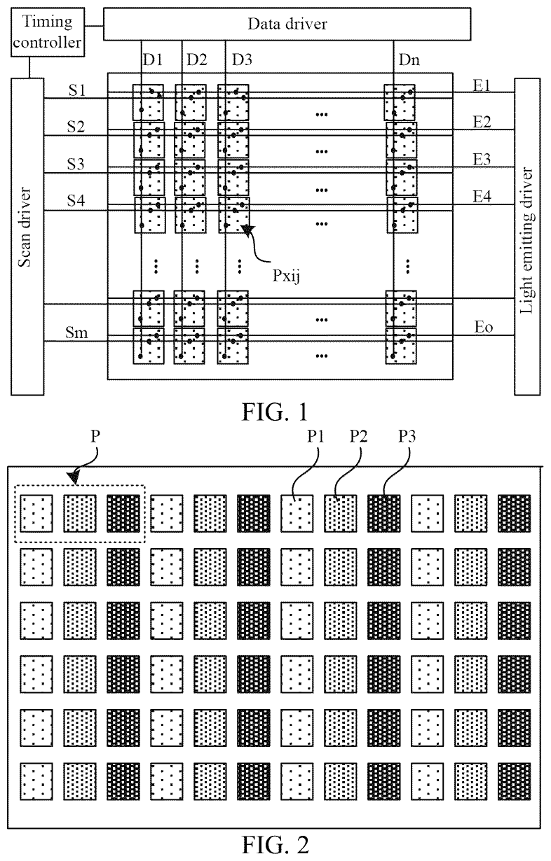

FIG. 1 is a schematic diagram of a structure of a display apparatus. As shown in FIG. 1, the display apparatus may include a timing controller, a data driver, a scan driver, a light emitting driver, and a pixel array. The timing controller is connected to the data driver, the scan driver, and the light emitting driver, respectively. The data driver is connected to multiple data signal lines (D1 to Dn) respectively. The scan driver is connected to multiple scan signal lines (S1 to Sm) respectively. The light emitting driver is connected to multiple light emitting signal lines (E1 to Eo) respectively. The pixel array may include multiple sub-pixels Pxij, wherein i and j may be natural numbers. At least one sub-pixel Pxij may include a circuit unit and a light emitting device connected to the circuit unit, wherein the circuit unit may include a pixel drive circuit, and the pixel drive circuit is connected to a scan signal line, a data signal line, and a light emitting signal line, respectively. In an exemplary implementation, the timing controller may provide the data driver with a grayscale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate scan signals to be provided to the scan signal lines S1, S2, S3, . . . , and Sm by receiving the clock signal, the scan start signal and the like from the timing controller. For example, the scan driver may sequentially provide a scan signal with an on-level pulse to the scan signal lines S1 to Sm. For example, the scan driver may be constructed in a form of a shift register and generate a scan signal in a manner of sequentially transmitting the scan start signal provided in a form of an on level pulse to a next-stage circuit under control of the clock signal, wherein m may be a natural number. The light emitting driver may receive a clock signal, an emission stop signal, and the like from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

FIG. 2 is a schematic diagram of a planar structure of a display substrate. In an exemplary implementation, the display substrate may include multiple pixel units P arranged in a matrix, at least one pixel unit P may include a first sub-pixel P1 emitting a first color light, a second sub-pixel P2 emitting a second color light, and a third sub-pixel P3 emitting a third color light respectively. Each of the three sub-pixels may include a circuit unit and a light emitting unit. The circuit unit may include a pixel drive circuit. The pixel drive circuit is respectively connected to a scan signal line, a data signal line, and a light emitting signal line. The pixel drive circuit is configured to receive a data voltage transmitted by the data signal line and output a corresponding current to the light emitting unit under a control of the scan signal line and the light emitting signal line. The light emitting unit is configured to emit light of a corresponding brightness in response to a current output by the pixel drive circuit connected to the light emitting unit.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation, a sub-pixel may be in a shape of a rectangle, a rhombus, a pentagon, or a hexagon. Three sub-pixels may be provided side by side horizontally, side by side vertically, or in a manner like a Chinese character “ [symbol] ”.

In another exemplary implementation, the pixel unit P may include four sub-pixels, which may be arranged side by side horizontally, side by side vertically, in a diamond shape or in a square, which is not limited in the present disclosure.

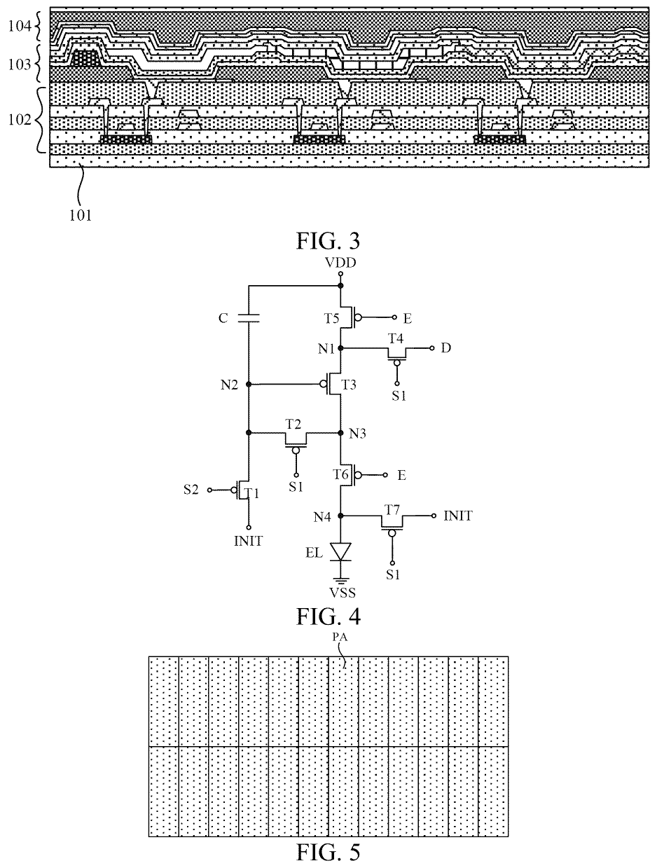

FIG. 3 is a schematic diagram of a sectional structure of a display substrate, and illustrates a structure of three sub-pixels of the display substrate. As shown in FIG. 3, on a plane perpendicular to the display substrate, the display substrate may include a drive circuit layer 102 arranged on a base substrate 101, a light emitting structure layer 103 arranged on a side of the drive circuit layer 102 away from the base substrate, and an encapsulation layer 104 arranged on a side of the light emitting structure layer 103 away from the base substrate. In some possible implementations, the display substrate may include another film layer, such as a post spacer, which is not limited in the present disclosure.

In an exemplary implementation, the base substrate 101 may be a flexible base substrate, or may be a rigid base substrate. The drive circuit layer 102 of each sub-pixel may include multiple circuit units which may include a pixel drive circuit formed by multiple transistors and a storage capacitor, and FIG. 3 is only illustrated by taking that the pixel drive circuit includes one drive transistor and one storage capacitor as an example. The light emitting structure layer 103 of each sub-pixel may include multiple light emitting units, and the emitting unit may include an anode, a pixel definition layer, an organic emitting layer, and a cathode, wherein the anode is connected to a drain electrode of a drive transistor through a via, the organic emitting layer is connected to the anode, the cathode is connected to the organic emitting layer, and the organic emitting layer emits light of a corresponding color under drive of the anode and the cathode. The encapsulation structure layer 104 may include a first encapsulation layer, a second encapsulation layer, and a third encapsulation layer that are stacked. The first encapsulation layer and the third encapsulation layer may be made of inorganic materials, and the second encapsulation layer may be made of an organic material. The second encapsulation layer is provided between the first encapsulation layer and the third encapsulation layer, which may ensure that external water vapor cannot enter the light emitting structure layer 103.

In an exemplary implementation, the organic emitting layer may include an Emitting Layer (EML) and any one or more of a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation, hole injection layers, electron injection layers, hole transport layers, electron transport layers, hole block layers and electron block layers of all light emitting units may be connected together to form a common layer. Emitting layers of adjacent light emitting units may be overlapped slightly, or may be isolated.

FIG. 4 is a schematic diagram of an equivalent circuit of a pixel drive circuit. In an exemplary implementation, the pixel drive circuit may have a structure of 3T1C, 4T1C, 5T1C, 5T2C, 6T1C, 7T1C, or 8T1C. As shown in FIG. 4, the pixel drive circuit may include seven transistors (a first transistor T1 to a seventh transistor T7), one storage capacitor C. The pixel drive circuit is connected to seven signal lines (a data signal line D, a first scan signal line S1, a second scan signal line S2, a light emitting signal line E, an initial signal line INIT, a first power supply line VDD, and a second power supply line VSS) respectively.

In an exemplary implementation, the pixel drive circuit may include a first node N1, a second node N2, a third node N3, and a fourth node N4. Among them, the first node N1 is connected to a first electrode of the third transistor T3, a second electrode of the fourth transistor T4, and a second electrode of the fifth transistor T5 respectively. The second node N2 is connected to a second electrode of the first transistor, a first electrode of the second transistor T2, a control electrode of the third transistor T3, and a second end of the storage capacitor C respectively. The third node N3 is connected to a second electrode of the second transistor T2, a second electrode of the third transistor T3, and a first electrode of the sixth transistor T6 respectively. The fourth node N4 is connected to a second electrode of the sixth transistor T6 and a second electrode of the seventh transistor T7 respectively.

In an exemplary implementation, a first end of the storage capacitor C is connected to the first power supply line VDD, and the second end of the storage capacitor C is connected to the second node N2, i.e., the second end of the storage capacitor C is connected to the control electrode of the third transistor T3.

The control electrode of the first transistor T1 is connected to the second scan signal line S2, the first electrode of the first transistor T1 is connected to the initial signal line INIT, and the second electrode of the first transistor is connected to the second node N2. When a scan signal with an on-level is applied to the second scan signal line S2, the first transistor T1 transmits an initialization voltage to the control electrode of the third transistor T3 so as to initialize a charge amount of the control electrode of the third transistor T3.

A control electrode of the second transistor T2 is connected to the first scan signal line S1, a first electrode of the second transistor T2 is connected to the second node N2, and a second electrode of the second transistor T2 is connected to the third node N3. When a scan signal with an on level is applied to the first scan signal line S1, the second transistor T2 enables the control electrode of the third transistor T3 to be connected to the second electrode of the third transistor T3.

A control electrode of the third transistor T3 is connected to the second node N2, i.e., the control electrode of the third transistor T3 is connected to the second end of the storage capacitor C, a first electrode of the third transistor T3 is connected to the first node N1, and the second electrode of the third transistor T3 is connected to the third node N3. The third transistor T3 may be referred to as a drive transistor, and the third transistor T3 determines an amount of a drive current flowing between the first power supply line VDD and the second power supply line VSS according to a potential difference between the control electrode and the first electrode of the third transistor T3.

A control electrode of the fourth transistor T4 is connected to the first scan signal line S1, a first electrode of the fourth transistor T4 is connected to the data signal line D, and a second electrode of the fourth transistor T4 is connected to the first node N1. The fourth transistor T4 may be referred to as a switching transistor, a scan transistor, and the like, and the fourth transistor T4 enables a data voltage of the data signal line D to be input into the pixel drive circuit when a scan signal with an on level is applied to the first scan signal line S1.

A control electrode of the fifth transistor T5 is connected to the light emitting signal line E, a first electrode of the fifth transistor T5 is connected to the first power supply line VDD, and a second electrode of the fifth transistor T5 is connected to the first node N1. The control electrode of the sixth transistor T6 is connected to the light emitting signal line E, the first electrode of the sixth transistor T6 is connected to the third node N3, and the second electrode of the sixth transistor T6 is connected to the first electrode of the light emitting device EL. The fifth transistor T5 and the sixth transistor T6 may be referred to as light emitting transistors. When a light emitting signal with an on-level is applied to the light emitting signal line E, the fifth transistor T5 and the sixth transistor T6 enable the light emitting device EL to emit light by forming a drive current path between the first power supply line VDD and the second power supply line VSS.

The control electrode of the seventh transistor T7 is connected to the first scan signal line S1, the first electrode of the seventh transistor T7 is connected to the initial signal line INIT, and the second electrode of the seventh transistor T7 is connected to the first electrode of the light emitting device EL. When a scan signal with an on-level is applied to the first scan signal line S1, the seventh transistor T7 transmits an initialization voltage to the first electrode of the light emitting device EL so as to initialize a charge amount accumulated in the first electrode of the light emitting device or release the charge amount accumulated in the first electrode of the light emitting device EL.

In an exemplary implementation, the light emitting device EL may be an OLED including a first electrode (anode), an organic emitting layer, and a second electrode (cathode) which are stacked, or may be a QLED including a first electrode (anode), a quantum dot light emitting layer, and a second electrode (cathode) which are stacked.

In an exemplary implementation, a second electrode of the light emitting device is connected to a second power supply line VSS, the signal of which is a continuously supplied low-level signal, and the signal of the first power supply line VDD is a continuously supplied high-level signal.

In an exemplary implementation, the first transistor T1 to the seventh transistor T7 may be P-type transistors, or may be N-type transistors. Use of a same type of transistors in a pixel drive circuit may simplify a process flow, reduce a process difficulty of a display panel, and improve a product yield. In some possible implementation, the first transistor T1 to the seventh transistor T7 may include a P-type transistor and an N-type transistor.

In an exemplary implementation, for the first transistor T1 to the seventh transistor T7, low temperature poly-crystalline silicon thin film transistors may be used, or oxide thin film transistors may be used, or both a low temperature poly-crystalline silicon thin film transistor and an oxide thin film transistor may be used. An active layer of a low temperature poly-crystalline silicon thin film transistor may be made of Low Temperature Poly-crystalline silicon (LTPS for short), and an active layer of an oxide thin film transistor may be made of an oxide semiconductor (Oxide). Low temperature poly-crystalline silicon thin film transistors have advantages such as high migration rate and fast charging, and oxide thin film transistors have advantages such as low leakage current. The low temperature poly-crystalline silicon thin film transistors and the oxide thin film transistors are integrated on one display substrate to form a low temperature polycrystalline oxide (LTPO) display substrate, so that the advantages of both the low temperature poly-crystalline silicon thin film transistors and the oxide thin film transistors can be utilized, low-frequency driving can be achieved, power consumption can be decreased, and display quality can be improved.

In an exemplary implementation, taking a case in which the seven transistors in the pixel drive circuit in FIG. 4 are all P-type transistors OLED as an example, the operation process of the pixel drive circuit may include following stages.

In a first stage A1, referred to as a reset stage, a signal of the second scan signal line S2 is a low-level signal, and signals of the first scan signal line S1 and the light emitting signal line E are high-level signals. The signal of the second scan signal line S2 is the low-level signal, so that the first transistor T1 is turned on, and a signal of the initial signal line INIT is provided to the second node N2 to initialize the storage capacitor C to clear an original data voltage in the storage capacitor. The signals of the first scan signal line S1 and the light emitting signal line E are the high-level signals, so that the second transistor T2, the fourth transistor T4, the fifth transistor T5, the sixth transistor T6, and the seventh transistor T7 are turned off. An OLED does not emit light in this stage.

In a second stage A2, referred to as a data writing stage or a threshold compensation stage, a signal of the first scan signal line S1 is a low-level signal, signals of the second scan signal line S2 and the light emitting signal line E are high-level signals, and the data signal line D outputs a data voltage. In this stage, the second end of the storage capacitor C is at a low level, so the third transistor T3 is turned on. The signal of the first scan signal line S1 is the low-level signal, so that the second transistor T2, the fourth transistor T4, and the seventh transistor T7 are turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd−|Vth|, wherein Vd is the data voltage output by the data signal line D, and Vth is the threshold voltage of the third transistor T3. The seventh transistor T7 is turned on, so that an initialization voltage of the initial signal line INIT is provided to a first electrode of the OLED to initialize (reset) the first electrode of the OLED and clear a pre-stored voltage therein, thereby completing initialization and ensuring that the OLED does not emit light. A signal of the second scan signal line S2 is a high-level signal, so that the first transistor T1 is turned off. A signal of the light emitting signal line E is a high-level signal, so that the fifth transistor T5 and the sixth transistor T6 are turned off.

In a third stage A3, referred to as a light emitting stage, a signal of the light emitting signal line E is a low-level signal, and signals of the first scan signal line S1 and the second scan signal line S2 are high-level signals. The signal of the light emitting signal line E is the low-level signal, so that the fifth transistor T5 and the sixth transistor T6 are turned on, and a power voltage output by the first power supply line VDD provides a drive voltage to the first electrode of the OLED through the turned-on fifth transistor T5, the third transistor T3, and the sixth transistor T6 to drive the OLED to emit light.

In a drive process of the pixel drive circuit, a drive current flowing through the third transistor T3 (drive transistor) is determined by a voltage difference between a gate electrode and the first electrode of the third transistor T3. Since the voltage of the second node N2 is Vd−|Vth|, the drive current of the third transistor T3 is as follows.

$$I = K * {( Vgs - Vth )}^{2} = K * {[ ( Vdd - Vd + \vert Vth \vert ) - Vth ]}^{2} = K * {[ ( Vdd - Vd ) ]}^{2}$$

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

An exemplary implementation of the present disclosure provides a display substrate. On a plane perpendicular to the display substrate, the display area may include a drive circuit layer arranged on the base substrate, a light emitting structure layer arranged on a side of the drive circuit layer away from the base substrate, and an encapsulation structure layer arranged on a side of the light emitting structure layer away from the base substrate. On a plane parallel to the display substrate, the drive circuit layer may include multiple circuit units, and the circuit units may at least include pixel drive circuits configured to output corresponding currents under the control of corresponding signal lines. The light emitting structure layer may include multiple light emitting units, and the light emitting units are connected to pixel drive circuits of the corresponding circuit units, and are configured to emit light of corresponding brightness in response to currents output by the connected pixel drive circuits.

In an exemplary implementation, the circuit units mentioned in the present disclosure refer to regions divided according to pixel drive circuits, and light emitting units mentioned in the present disclosure refer to regions divided according to light emitting devices. In an exemplary implementation, a position and shape of an orthographic projection of a light emitting unit on the base substrate may correspond to a position and shape of an orthographic projection of a circuit unit on the base substrate, or the position and shape of the orthographic projection of the light emitting unit on the base substrate may not correspond to the position and shape of the orthographic projection of the circuit unit on the base substrate.

FIG. 5 is a schematic diagram of an arrangement of a circuit unit according to an exemplary embodiment of the present disclosure. As shown in FIG. 5, in an exemplary implementation, on a plane parallel to the display substrate, a drive circuit layer of the display area may include multiple circuit units PA, and the multiple circuit units PA may constitute multiple unit rows and multiple unit columns. The unit row may include multiple circuit units PA sequentially provided in a first direction X, the unit column may include multiple circuit units PA sequentially provided in a second direction Y, and the first direction X intersects with the second direction Y.

In an exemplary implementation, a shape of the circuit unit PA may be a rectangular shape, a long side of the circuit unit PA in a rectangular shape may extend along the second direction Y (column direction), and a short side of the circuit unit PA in a rectangular shape may extend along the first direction X (row direction), forming an arrangement of horizontal parallel units.

In an exemplary implementation, the circuit unit PA may at least include a pixel drive circuit. The pixel drive circuit is connected to a scan signal line, a data signal line, and a light emitting signal line, respectively, and configured to receive a data voltage transmitted by the data signal line and output a corresponding current to the connected light emitting unit under control of the scan signal line and the light emitting signal line.

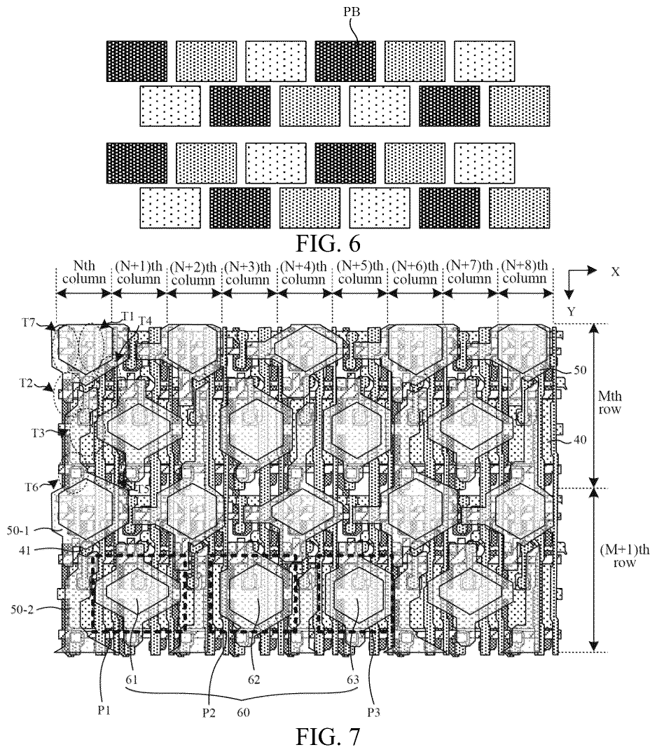

FIG. 6 is a schematic diagram of an arrangement of light emitting units according to an exemplary embodiment of the present disclosure. As shown in FIG. 6, in an exemplary implementation, on a plane parallel to the display substrate, a light emitting structure layer of a display substrate may include multiple light emitting units PB arranged regularly, the multiple light emitting units PB may constitute multiple sub-pixel rows and multiple sub-pixel columns. A sub-pixel row may include multiple light emitting units PB sequentially provided in a first direction X, and a sub-pixel column may include multiple light emitting units PB sequentially provided in a second direction Y.

In an exemplary implementation, multiple light emitting units PB may include a red light emitting unit emitting red light, a blue light emitting unit emitting blue light, and a green light emitting unit emitting green light. The red light emitting unit, the blue light emitting unit, and the green light emitting unit in each sub-pixel row may be arranged periodically in the first direction X. The red light emitting units, the blue light emitting units, and the green light emitting units of odd-numbered sub-pixel rows and even-numbered sub-pixel rows are staggered. Six light emitting units share one surrounding light emitting unit, forming a Delta pixel arrangement, and the Delta pixel arrangement has a characteristic of a large pixel aperture ratio.

In an exemplary implementation, a light emitting unit is connected to a pixel drive circuit of a corresponding circuit unit, and is configured to emit light of a corresponding brightness in response to a current output by the pixel drive circuit connected to the light emitting unit.

In an exemplary implementation, a shape of the light emitting unit PB may include any one or more of the following: a triangle, a rectangle, a diamond, a pentagon, and a hexagon.

An exemplary embodiment of the present disclosure provides a display substrate including multiple sub-pixels and a pixel definition layer, multiple pixel openings are formed in the pixel definition layer, and each sub-pixel includes at least one pixel opening.

The multiple sub-pixels include a first sub-pixel, a second sub-pixel, and a third sub-pixel, wherein at least one first sub-pixel is adjacent to a second sub-pixel and a third sub-pixel, and a closest distance between a pixel opening of the at least one first sub-pixel and a pixel opening of an adjacent second sub-pixel is different from a closest distance between the pixel opening of the at least one first sub-pixel and a pixel opening of an adjacent third sub-pixel.

In the display substrate provided by an embodiment of the present disclosure, at least one first sub-pixel is adjacent to a second sub-pixel and a third sub-pixel, and the closest distance between the pixel opening of the at least one first sub-pixel and the pixel opening of the adjacent second sub-pixel is different from the closest distance between the pixel opening of the at least one first sub-pixel and the pixel opening of the adjacent third sub-pixel, so that an anode compensation space of at least one of the second sub-pixel and the third sub-pixel can be adjusted, thereby a parasitic capacitance in the sub-pixel can be adjusted to make the parasitic capacitances in multiple sub-pixels as consistent as possible.

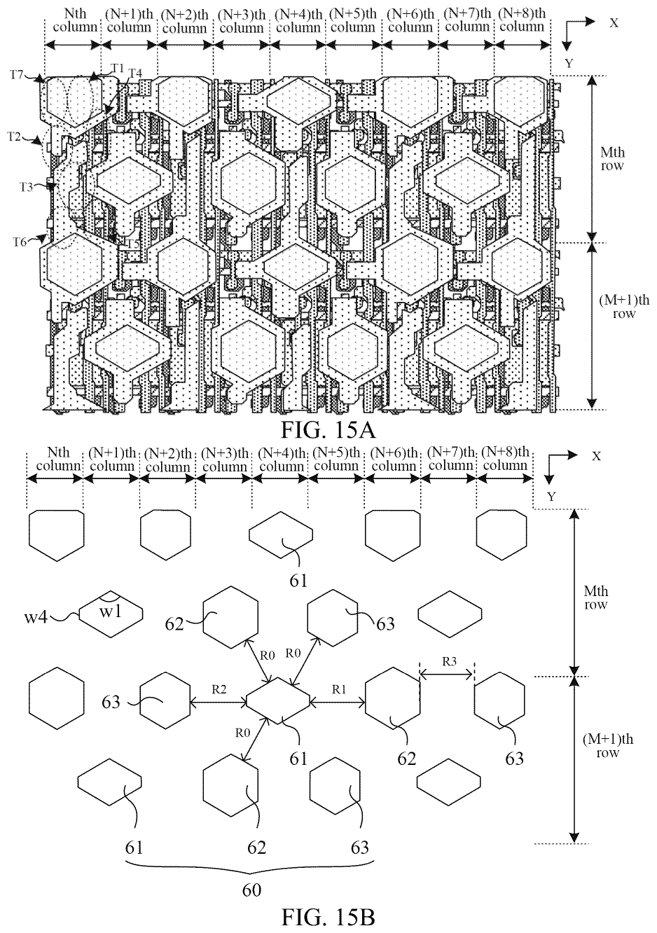

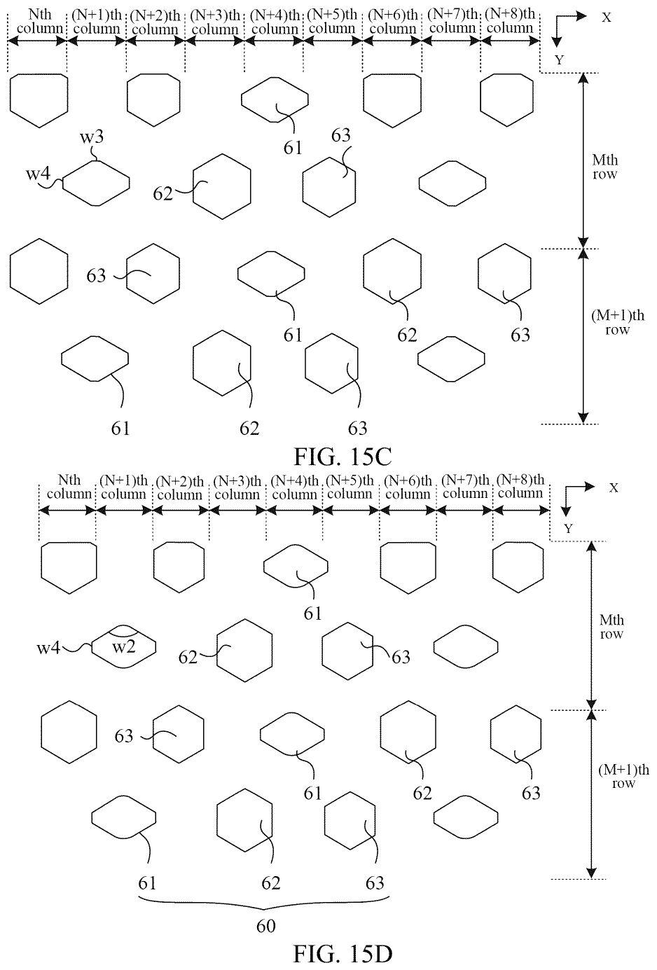

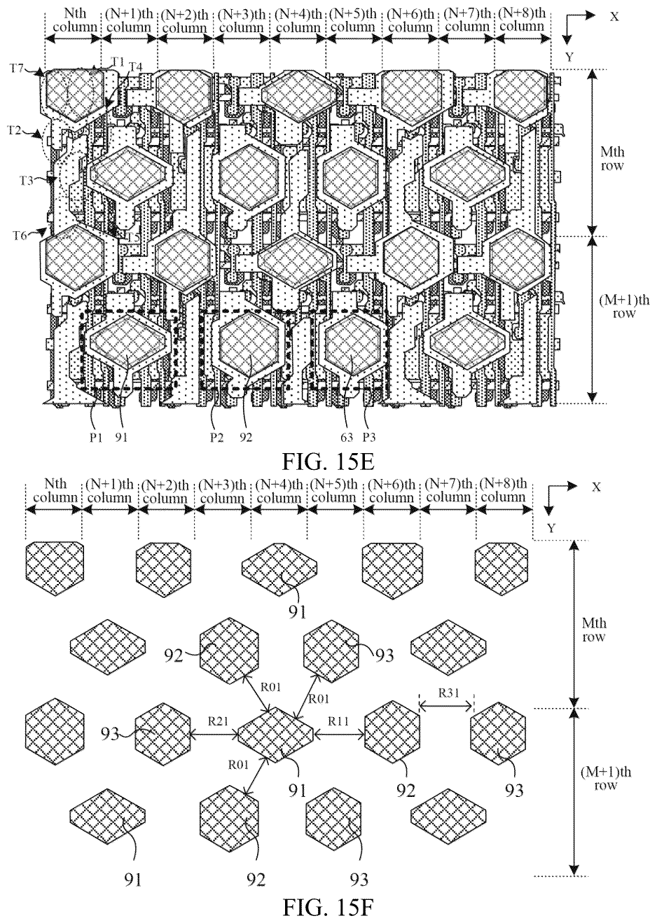

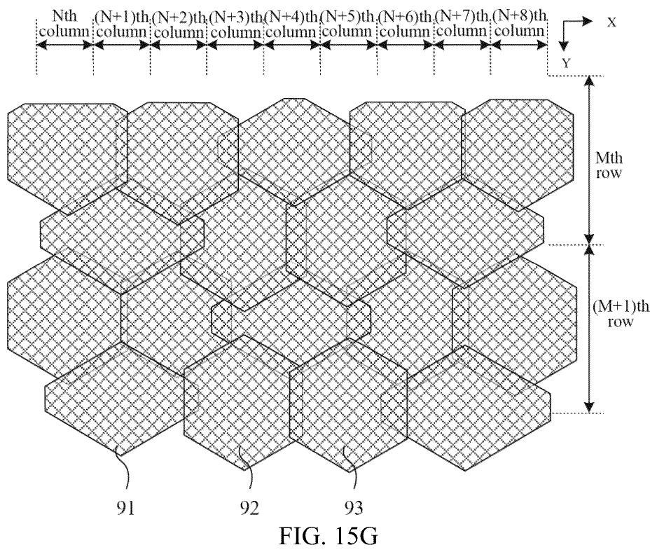

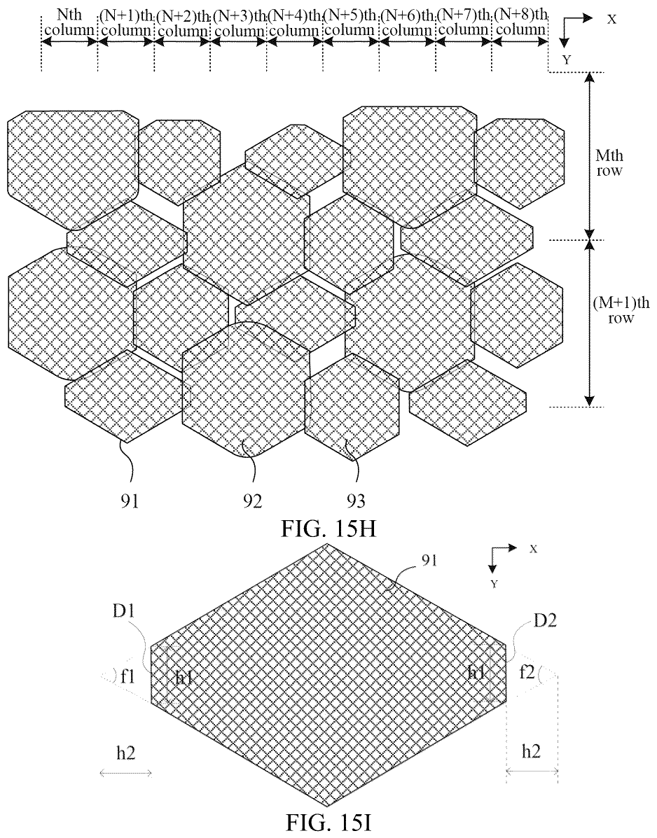

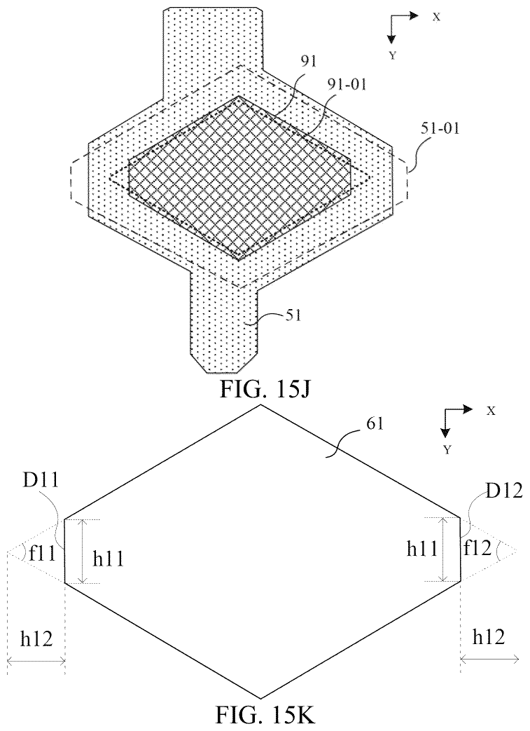

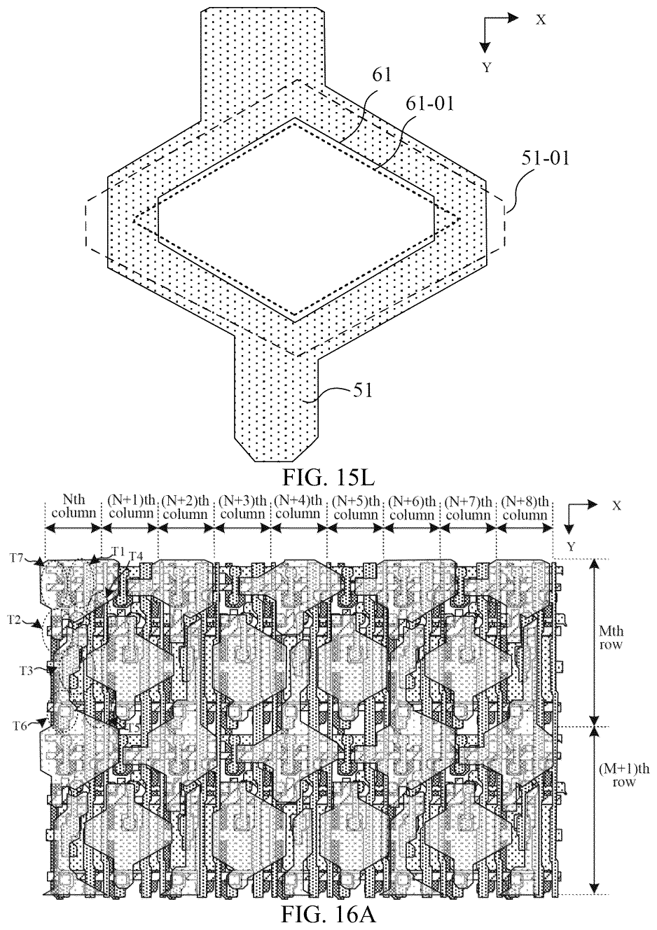

The display substrate provided by an embodiment of the present disclosure may be shown in FIG. 7 and FIG. 15B, the display substrate may include multiple sub-pixels and a pixel definition layer, multiple pixel openings (61, 62, 63) are formed in the pixel definition layer, and each sub-pixel may include at least one pixel opening.

Multiple sub-pixels include a first sub-pixel P1, a second sub-pixel P2, and a third sub-pixel P3. At least one first sub-pixel P1 is adjacent to a second sub-pixel P2 and a third sub-pixel P3, and a closest distance between a pixel opening 61 of at least one first sub-pixel P1 and a pixel opening 62 of an adjacent second sub-pixel P2 is different from a closest distance between the pixel opening 61 of the at least one first sub-pixel P1 and a pixel opening 63 of an adjacent third sub-pixel P3. For example, in a same sub-pixel row, a closest distance R1 from a pixel opening 61 of a first sub-pixel P1 to a pixel opening 62 of an adjacent second sub-pixel P2 is different from a closest distance R2 from the pixel opening 61 of the at least one first sub-pixel P1 to a pixel opening 63 of an adjacent third sub-pixel P3; or, a closest distance from a pixel opening 61 of a first sub-pixel P1 to a pixel opening 62 of an adjacent second sub-pixel P2 located in an adjacent sub-pixel row may be different from a closest distance from the pixel opening 61 of the first sub-pixel P1 to a pixel opening 63 of an adjacent third sub-pixel P3 located in the same sub-pixel row as the first sub-pixel P1.

In an exemplary implementation, as shown in FIG. 7 and FIG. 15B, at least one first sub-pixel P1 is at least adjacent to two second sub-pixels P2, and at least one first sub-pixel P1 is at least adjacent to two third sub-pixels P3, and a closest distance from a pixel opening 61 of at least one first sub-pixel P1 to a pixel opening 62 of another adjacent second sub-pixel P2 may be the same as a closest distance from the pixel opening 61 of the at least one first sub-pixel P1 to a pixel opening 63 of another adjacent third sub-pixel P3. For example, as shown in FIG. 15B, a closest distance between a pixel opening 61 of a first sub-pixel P1 and a pixel opening 62 of an adjacent second sub-pixel P2 in an adjacent sub-pixel row may be the same as a closest distance between the pixel opening 61 of the first sub-pixel P1 and a pixel opening 63 of an adjacent third sub-pixel P3 in an adjacent sub-pixel row.

In an exemplary implementation, as shown in FIG. 7 and FIG. 15B, in a first direction X one first sub-pixel P1, one second sub-pixel P2, and one third sub-pixel P3 are sequentially arranged, and a closest distance R1 between a pixel opening 61 of a first sub-pixel P1 and a pixel opening 62 of a second sub-pixel P2 is different from a closest distance R3 between the pixel opening 62 of the second sub-pixel P2 and a pixel opening 63 of a third sub-pixel P3. The first direction X is one of a row direction or a column direction, and the first direction X in FIG. 15B is a row direction of the sub-pixels. Anode compensation spaces in the first sub-pixel P1, the second sub-pixel P2, and the third sub-pixel P3 may be adjusted to make parasitic capacitances in multiple sub-pixels as consistent as possible.

In an exemplary implementation, as shown in FIG. 7 and FIG. 15B, at least one first sub-pixel P1 is at least adjacent to two second sub-pixels P2, and closest distances between a pixel opening 61 of the at least one first sub-pixel P1 and pixel openings 62 of two adjacent second sub-pixels P2 are different. For example, a closest distance R1 between a pixel opening 61 of a first sub-pixel P1 and a pixel opening 62 of an adjacent second sub-pixel P2 located in the same sub-pixel row is different from a closest distance R0 between the pixel opening 61 of the first sub-pixel P1 and a pixel opening 62 of an adjacent second sub-pixel P2 located in an adjacent sub-pixel row.

In an exemplary implementation, as shown in FIG. 7 and FIG. 15B, at least one first sub-pixel P1 is at least adjacent to two third sub-pixels P3, and closest distances between a pixel opening 61 of the at least one first sub-pixel P1 and pixel openings 63 of two adjacent third sub-pixels P3 are different. For example, a closest distance R2 between a pixel opening 61 of a first sub-pixel P1 and a pixel opening 63 of an adjacent third sub-pixel P3 located in the same sub-pixel row is different from a closest distance R0 between the pixel opening 61 of the first sub-pixel P1 and a pixel opening 63 of an adjacent third sub-pixel P3 located in an adjacent sub-pixel row.

In an exemplary implementation, as shown in FIG. 7 and FIG. 15B, a closest distance from a pixel opening of a sub-pixel located in the same row as the at least one first sub-pixel P1 and adjacent to the at least one first sub-pixel P1 to a pixel opening 61 of the at least one first sub-pixel P1 is different from a closest distance from a pixel opening of a sub-pixel located in a different row from the at least one first sub-pixel P1 and adjacent to the at least one first sub-pixel P1 to the pixel opening 61 of the at least one first sub-pixel P1. As shown in FIG. 15B, sizes of closest distances R1, R2, R3 are different from a size of the closest distance R0.

In an exemplary implementation, as shown in FIG. 7 and FIG. 15B, the closest distance from the pixel opening of the sub-pixel located in the same row as the at least one first sub-pixel P1 and adjacent to the at least one first sub-pixel P1 to the pixel opening 61 of the at least one first sub-pixel P1 is greater than the closest distance R0 from the pixel opening of the sub-pixel located in a different row from the at least one first sub-pixel P1 and adjacent to the at least one first sub-pixel P1 to the pixel opening 61 of the at least one first sub-pixel P1. As shown in FIG. 15B, the sizes of the closest distances R1, R2, R3 may be greater than the size of the closest distance R0.

In an exemplary implementation, as shown in FIG. 15B to FIG. 15D, opposite sides w4 of pixel openings of at least a portion of sub-pixels and pixel openings of a portion of adjacent sub-pixels may be parallel sides, and parts of pixel openings of the at least a portion of sub-pixels opposite to the pixel openings of other adjacent sub-pixels may include an angle w1, a rounded angle w2, or a side w3 with a side length is less than 1/10 of perimeter of the pixel opening thereof. For example, in FIG. 15B to FIG. 15D, two opposite sides of the pixel opening 61 of a first sub-pixel P1 in the first direction X are parallel sides w4; in FIG. 15B, opposite parts in the second direction Y are two opposite angles w1; as shown in FIG. 15D, opposite parts in the second direction Y are two opposite rounded angles w2; as shown in FIG. 15C, opposite parts w3 in the second direction Y are less than 1/10 of a perimeter of the pixel opening 61 of the first sub-pixel P1.

In an exemplary implementation, as shown in FIG. 15E and FIG. 15F, multiple sub-pixels may include light emitting layers corresponding to pixel openings, wherein a first sub-pixel P1 includes a first light emitting layer 91, a second sub-pixel P2 includes a second light emitting layer 92, and a third sub-pixel P3 includes a third light emitting layer 93.

A closest distance from the at least one first light emitting layer 91 to an adjacent second light emitting layer 92 is different from a closest distance from the at least one first light emitting layer 91 to an adjacent third light emitting layer 93. For example, in a same sub-pixel row, a closest distance R11 from a first light emitting layer 91 to an adjacent second light emitting layer is different from a closest distance R21 from the first light emitting layer 91 to an adjacent third light emitting layer 93; or, a closest distance from a first light emitting layer 91 to an adjacent second light emitting layer 92 located in an adjacent sub-pixel row may be different from a closest distance from the first light emitting layer 91 to an adjacent third light emitting layer 93 located in the same sub-pixel row as the first light emitting layer 91.

In an exemplary implementation, as shown in FIG. 15F, light emitting layers of at least a portion of adjacent sub-pixels are spaced, and spacings between the light emitting layers of different sub-pixels are different; or as shown in FIG. 15G, light emitting layers of at least a portion of adjacent sub-pixels are overlapped and overlapping areas thereof are different; or as shown in FIG. 15H, light emitting layers of a portion of adjacent sub-pixels are overlapped, and light emitting layers of a portion of adjacent sub-pixels are spaced.

In an exemplary implementation, as shown in FIG. 15H, shapes of light emitting layers of at least a portion of the sub-pixels are different from shapes of corresponding pixel openings. Shapes of at least a portion of light emitting layers in FIG. 15H are different from shapes of corresponding pixel openings in FIG. 15B, for example, a shape of a second light emitting layer 92 is different from a shape of a corresponding pixel opening 62. As shown in FIG. 15F, shapes of at least a portion of light emitting layers may be the same as shapes of corresponding pixel openings in FIG. 15B.

In an exemplary implementation, as shown in FIG. 15F, at least one first light emitting layer 91 is at least adjacent to two second light emitting layers 92, and at least one first light emitting layer 91 is at least adjacent to two third light emitting layers 93, and a closest distance from at least one first light emitting layer 91 to another adjacent second light emitting layer 92 is the same as a closest distance from the at least one first light emitting layer 91 to another adjacent third light emitting layer 93. For example, as shown in FIG. 15F, a closest distance between a first light emitting layer 91 and an adjacent second light emitting layer 92 located in an adjacent sub-pixel row may be the same as a closest distance between the first light emitting layer 91 and an adjacent third light emitting layer 93 located in an adjacent sub-pixel row.

In an exemplary implementation, as shown in FIG. 15F, in a first direction X, one first light emitting layer 91, one second light emitting layer 92, and one third light emitting layer 93 are sequentially arranged, and a closest distance R11 between the first light emitting layer 91 and the second light emitting layer 92 is different from a closest distance R31 between the second light emitting layer 92 and the third light emitting layer 93, and the first direction X is one of a row direction or a column direction. The first direction X shown in FIG. 15F may be the row direction.

In an exemplary implementation, as shown in FIG. 15F, the at least one first light emitting layer 91 is at least adjacent to two second light emitting layers 92, and closest distances between the at least one first light emitting layer 91 and adjacent two second light emitting layers 92 are different. For example, a closest distance R11 between a first light emitting layer 91 and an adjacent second light emitting layer 92 located in the same sub-pixel row is different from a closest distance R01 between the first light emitting layer 91 and an adjacent second light emitting layer 92 located in an adjacent sub-pixel row.

In an exemplary implementation, as shown in FIG. 15F, the at least one first light emitting layer 91 is at least adjacent to two third light emitting layers 93, and closest distances between the at least one first light emitting layer 91 and adjacent two third light emitting layers 93 are different. For example, a closest distance R21 between a first light emitting layer 91 and an adjacent third light emitting layer 93 located in the same sub-pixel row is different from a closest distance R01 between the first light emitting layer 91 and an adjacent third light emitting layer 93 located in an adjacent sub-pixel row.

In an exemplary implementation, as shown in FIG. 15F, a closest distance from a light emitting layer located in the same row as the at least one first light emitting layer 91 and adjacent to the at least one first light emitting layer 91 to the at least one first light emitting layer 91 is different from a closest distance from a light emitting layer located in a different row from the at least one first light emitting layer 91 and adjacent to the at least one first light emitting layer 91 to the at least one first light emitting layer 91. As in FIG. 15F, sizes of closest distances R11, R21, R31 are different from a size of a closest distance R01.

In an exemplary implementation, the closest distance from the light emitting layer located in the same row as the at least one first light emitting layer 91 and adjacent to the at least one first light emitting layer 91 to the at least one first light emitting layer 91 is greater than the closest distance from the light emitting layer located in a different row from the at least one first light emitting layer 91 and adjacent to the at least one first light emitting layer 91 to the at least one first light emitting layer. As in FIG. 15F, the sizes of the closest distances R11, R21, R31 may be greater than the size of the closest distance R01.

In an exemplary implementation, as shown in FIG. 15I and FIG. 15J, a shape of at least one first light emitting layer 91 may be a hexagon, and the hexagonal first light emitting layer 91 may include a first edge D1 and a second edge D2 provided oppositely in a row direction, and in the row direction, the first edge D1 of the first light emitting layer 91 is adjacent to an adjacent third light emitting layer 93, the second edge D2 of the first light emitting layer 91 is adjacent to an adjacent second light emitting layer 92, and a size of the second edge D2 in the column direction is greater than or equal to a size of the first edge D1 in the column direction. In an exemplary implementation, the row direction may be a first direction X, and the column direction may be a second direction Y, the first direction X may intersect with the second direction Y, for example, the first direction X may be perpendicular to the second direction Y.

In an exemplary implementation, as shown in FIG. 15I, at least one of the first edge D1 and the second edge D2 has a size h1 of 4 microns to 9 microns in the column direction.

In an exemplary implementation, as shown in FIG. 15I and FIG. 15J, in the same sub-pixel row and in the first direction X, the first edge D1 of the first light emitting layer 91 is close to an adjacent third light emitting layer 93, the second edge D2 of the first light emitting layer 91 is close to an adjacent second light emitting layer 92, and a size of the second edge D2 in the second direction Y is greater than or equal to a size of the first edge D1 in the second direction Y.

In an exemplary implementation, as shown in FIG. 15I, a rhombus in which the hexagonal first light emitting layer 91 is located may include a first included angle f1 and a second included angle f2 oppositely arranged in a row direction, in the row direction, the first included angle f1 is located on a side of the first edge D1 away from the second edge D2, the second included angle f2 is located on a side of the second edge D2 away from the first edge D1, and a distance between a vertex of the second included angle f2 and the second edge D2 is greater than or equal to a distance between a vertex of the first included angle f1 and the first edge D1. In a structure in which the distance between the vertex of the second included angle f2 and the second edge D2 is greater than the distance between the vertex of the first included angle f1 and the first edge D1, an anode compensation space of the second light emitting layer 92 is relatively great.

In an exemplary implementation, in the row direction, a distance between at least one of the first edge D1 and the second edge D2 and a vertex of an included angle adjacent thereto is 3 microns to 6 microns. In an exemplary implementation, a distance h2 between the first edge D1 and the vertex of the first included angle f1 in the first direction X (the row direction) is 3 microns to 6 microns, and a distance h2 between the second edge D2 and the vertex of the second included angle f2 in the first direction X (the row direction) is 3 microns to 6 microns.

In an exemplary implementation, as shown in FIG. 15I, a size h1 of at least one of the first edge D1 and the second edge D2 in the second direction Y may be 7.8716 microns, a distance h2 between the first edge D1 and the vertex of the first included angle f1 in the first direction X may be 5.2314 microns, and a distance h2 between the second edge D2 and the vertex of the second included angle f2 in the first direction X may be 5.2314 microns; or, a size h1 of at least one of the first edge D1 and the second edge D2 in the second direction Y may be 5.7919 microns, a distance h2 between the first edge D1 and the vertex of the first included angle f1 in the first direction X may be 3.6432 microns, and a distance h2 between the second edge D2 and the vertex of the second included angle f2 in the first direction X may be 3.6432 microns.

In an exemplary implementation, the first sub-pixel may be a sub-pixel emitting red light, the second sub-pixel may be a sub-pixel emitting blue light, and the third sub-pixel may be a sub-pixel emitting green light.

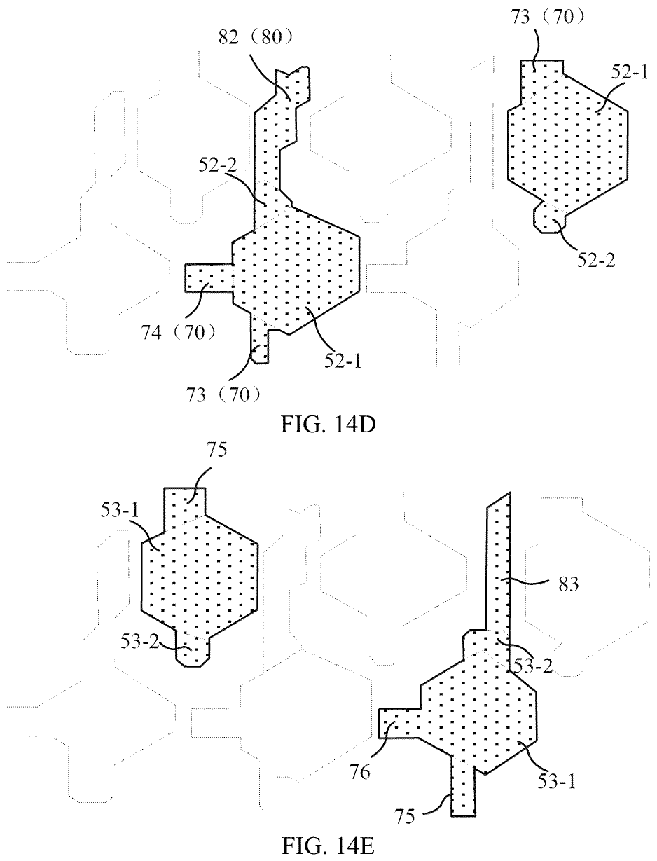

In an exemplary implementation, as shown in FIG. 7 and FIG. 14A to FIG. 14B, the display substrate may further include a drive circuit layer provided on a base substrate, the drive circuit layer may include multiple circuit units, multiple sub-pixels may include light emitting units and circuit units. A light emitting unit may be provided on a side of the drive circuit layer away from the base substrate, the light emitting unit includes an anode and a light emitting layer; the light emitting layer is located on a side of the anode away from the drive circuit layer. A circuit unit at least includes a pixel drive circuit, the pixel drive circuit at least includes a storage capacitor and a compensation transistor T2, and a first electrode of the compensation transistor T2 is connected to a first plate of the storage capacitor through a first connection electrode 41. An anode 50 of the light emitting unit is connected to a pixel drive circuit. In the row direction, an orthographic projection of the anode 50 of at least one light emitting unit on the base substrate is not overlapped with an orthographic projection of the first connection electrode 41 in the circuit unit adjacent to the anode 50 on at least one side on the base substrate. In the column direction, an orthographic projection of the anode 50 of at least one light emitting unit on the base substrate is at least partially overlapped with an orthographic projection of the first connection electrode 41 in the circuit unit adjacent to the anode 50 on at least one side on the base substrate.

In an exemplary implementation, as shown in FIG. 7, multiple light emitting units may form multiple sub-pixel rows, and a sub-pixel row includes multiple light emitting units arranged sequentially in the row direction. Multiple circuit units may form multiple unit rows, and a unit row may include multiple circuit units arranged sequentially in the row direction. Multiple sub-pixel rows may include multiple first sub-pixel rows and multiple second sub-pixel rows, the first sub-pixel rows and the second sub-pixel rows arranged alternately in the column direction, positions of multiple pixel drive circuits of one unit row correspond to positions of multiple light emitting units of two adjacent sub-pixel rows. In the column direction, an orthographic projection of the anodes 50 of the multiple light emitting units in the first sub-pixel row on the base substrate is at least partially overlapped with an orthographic projection of the first connection electrode 41 in an adjacent unit row on the base substrate, and an orthographic projection of the anodes 50 of the multiple light emitting units in the second sub-pixel row on the base substrate is at least partially overlapped with an orthographic projection of the first connection electrode 41 in a corresponding unit row on the base substrate.

In an exemplary implementation, as shown in FIG. 7 and FIG. 14C to FIG. 14E, an anode 50 of at least one light emitting unit located in the first sub-pixel row may include an anode main body part 50-1, an anode connection part 50-2, and an anode compensation part 80. The anode connection part 50-2 is configured to be connected to the pixel drive circuit, and the anode compensation part 80 is provided on a side of the anode connection part 50-2 away from the anode main body part 50-1. The anode main body part 50-1 may include an anode main body part 51-1 in FIG. 14C, an anode main body part 52-1 in FIG. 14D, and an anode main body part 53-1 in FIG. 14E. The anode connection part 50-2 may include an anode connection part 51-2 in FIG. 14C, an anode connection part 52-2 in FIG. 14D, and an anode connection part 53-2 in FIG. 14E. The anode compensation part 80 may include an anode compensation part 81 in FIG. 14C, an anode compensation part 82 in FIG. 14D, and an anode compensation part 83 in FIG. 14E.

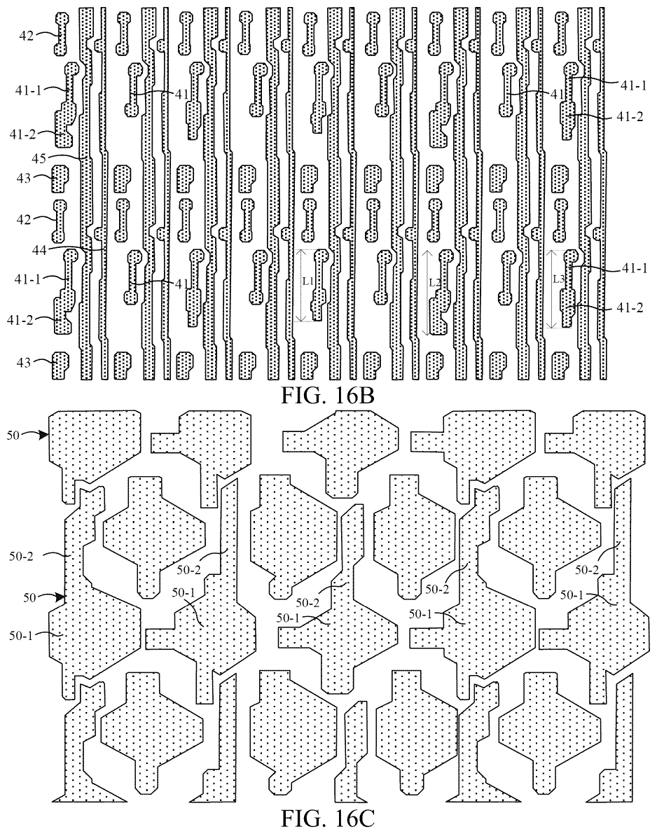

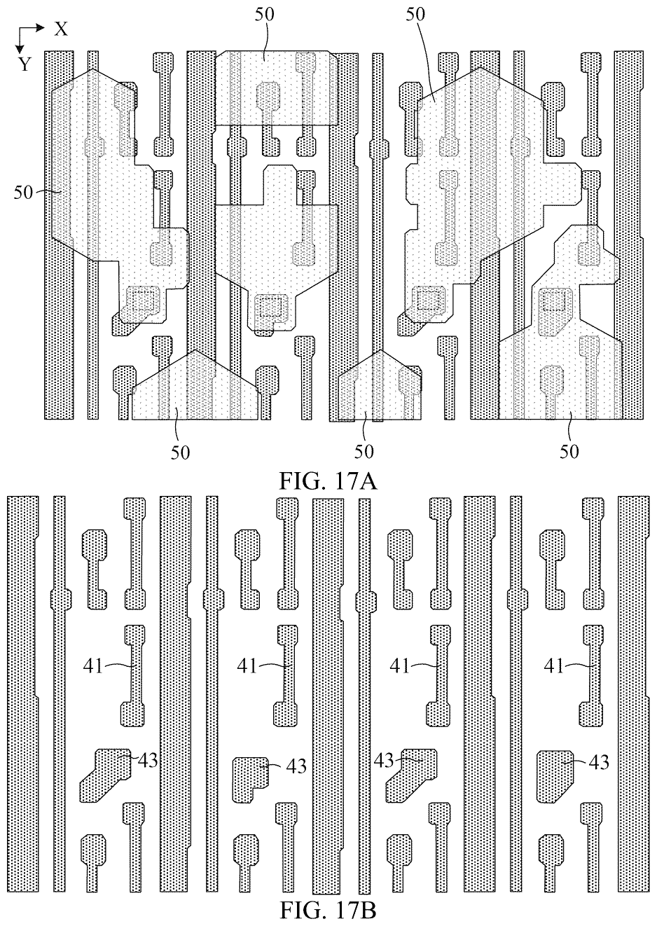

In an exemplary implementation, as shown in FIG. 16A and FIG. 16B, the first connection electrode 41 may include an electrode main body part 41-1 and an electrode compensation part 41-2, the electrode main body part 41-1 includes a first end connected to a first plate of the storage capacitor and a second end connected to a first electrode of the compensation transistor T2, and the electrode compensation part 41-2 is provided on a side of the first end away from the second end.

In an exemplary implementation, as shown in FIG. 16A to FIG. 16C, in at least one circuit unit, an orthographic projection of an anode compensation part 80 on the base substrate is at least partially overlapped with an orthographic projection of an electrode compensation part 41-2 of a first connection electrode 41 on the base substrate; in at least one circuit unit, an orthographic projection of an anode compensation part 80 on the base substrate is at least partially overlapped with an orthographic projection of an electrode main body part 41-1 of a first connection electrode 41 on the base substrate.

In an exemplary implementation, as shown in FIG. 7, FIG. 16A to FIG. 16C, in at least one light emitting unit located in a first sub-pixel row, an orthographic projection of an anode main body part 50-1 on the base substrate is not overlapped with an orthographic projection of a first connection electrode 41 on the base substrate; in at least one light emitting unit located in a second sub-pixel row, an orthographic projection of an anode main body part 50-1 on the base substrate is at least partially overlapped with an orthographic projection of a first connection electrode 41 on the base substrate.

In an exemplary implementation, as shown in FIG. 7 and FIG. 16A, in at least one light emitting unit located in the first sub-pixel row, an orthographic projection of an anode compensation part 80 on the base substrate is at least partially overlapped with an orthographic projection of a first connection electrode 41 in an adjacent unit row on the base substrate.

In an exemplary implementation, as shown in FIG. 7, FIG. 14A to FIG. 14E, an anode of at least one light emitting unit located in a second sub-pixel row includes an anode main body part 50-1, an anode connection part 50-2, and the anode connection part 50-2 is configured to be connected to a pixel drive circuit.

In an exemplary implementation, as shown in FIG. 7, FIG. 14A to FIG. 14E, the anode further includes a protrusion part 70, the protrusion part 70 is provided on a side of the anode main body part 50-1 away from the anode connection part 50-2, and an orthographic projection of protrusion parts 70 of multiple light emitting units in any sub-pixel row on the base substrate is at least partially overlapped with an orthographic projection of multiple first connection electrodes 41 in the corresponding unit row on the base substrate, respectively.

In an exemplary implementation, as shown in FIG. 7, multiple sub-pixel columns include multiple first sub-pixel columns and multiple second sub-pixel columns, the first sub-pixel columns and the second sub-pixel columns are alternately arranged in the row direction, multiple light emitting units in a first sub-pixel column are located in a first sub-pixel row, and multiple light emitting units in a second sub-pixel column are located in a second sub-pixel row.

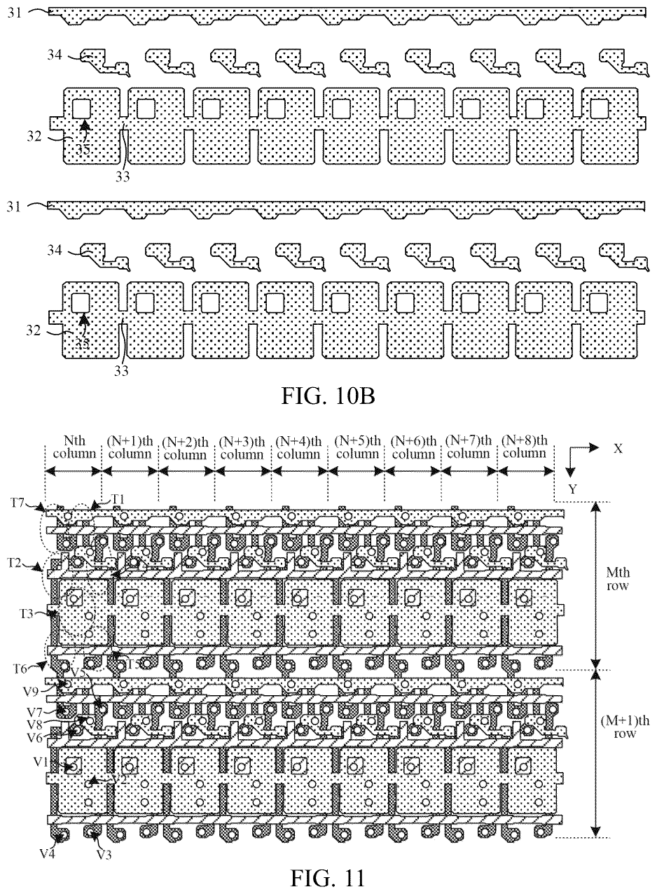

In an exemplary implementation, as shown in FIG. 7 and FIG. 10B, the storage capacitor may include a first plate 24 and a second plate 32, an opening 35 is provided on the second plate 32, positions of multiple light emitting units of one sub-pixel column correspond to positions of multiple circuit units of one unit column, multiple unit columns include multiple first unit columns and multiple second unit columns, the first unit columns and the second unit columns are arranged alternately in the first direction X, an orthographic projection of anode compensation parts 80 of multiple light emitting units in a first sub-pixel column on the base substrate is at least partially overlapped with an orthographic projection of openings 35 on second plates 32 of multiple circuit units in a corresponding first unit column on the base substrate respectively, and the orthographic projection of the anode compensation parts 80 of the multiple light emitting units in the first sub-pixel column on the base substrate is at least partially overlapped with an orthographic projection of first connection electrodes 41 of multiple circuit units in a corresponding first unit column on the base substrate, respectively.

In an exemplary implementation, as shown in FIG. 7, FIG. 10B, FIG. 16A to FIG. 16C, an orthographic projection of anode main body parts of multiple light emitting units in a second sub-pixel column on the base substrate is at least partially overlapped with an orthographic projection of openings 35 on the second plates of multiple circuit units in a corresponding second unit column on the base substrate, respectively, and the orthographic projection of the anode main body parts of the multiple light emitting units in the second sub-pixel column on the base substrate is at least partially overlapped with an orthographic projection of first connection electrodes 41 of multiple circuit units in a corresponding second unit column on the base substrate, respectively.

In an implementation of the present disclosure, as shown in FIG. 15A to FIG. 15J, sizes of a first anode 51 in a first light emitting unit emitting red light and a corresponding pixel opening 61 in the first direction X are contracted, so that an orthographic projection of anode compensation part 82 in a second anode 52 in second light emitting unit and an orthographic projection of anode compensation part 83 in a third anode 53 in third light emitting unit can be at least partially overlapped with an orthographic projection of a first connection electrode 41 on the base substrate, wherein the second anode 52 and the third anode 53 are located on two sides of the first anode 51, and differences of parasitic capacitances generated by a first sub-pixel column and a second sub-pixel column and the corresponding unit columns can be reduced as much as possible.

In the related art, under a condition that sizes of a first anode 51 and a corresponding pixel opening 61 and a first light emitting layer 91 in the first direction X are not contracted, a size h1 of the first edge D1 and the second edge D2 in the second direction Y are usually 0.4 microns. During production, due to a small size, first light emitting layers 91 of some first light emitting units and first edges D1 and second edges D2 of some pixel openings 61 often form an arc shape due to process fluctuations, resulting in inconsistent shapes of the first light emitting layers 91 of the first light emitting units. In an embodiment of the present disclosure, the size h1 of the first edge D1 and the second edge D2 in the second direction Y are slightly increased from 0.4 microns to 4-9 microns, which overcomes the defect of the inconsistent shapes of first light emitting layers 91 of multiple first light emitting units and pixel openings 61 of the multiple first light emitting units due to the small size and process fluctuations. On another aspect, compared with uncontracted sizes of the first anode 51 and the corresponding pixel opening 61 and the first light emitting layer 91 in the first direction X in the related art, the first anode 51 and the corresponding pixel opening 61 are contracted unilaterally by 3 microns to 6 microns in the first direction X in an embodiment of the present disclosure, as shown in FIG. 15I, compensation spaces of a compensation part 82 of the second anode 52 and a compensation part 83 of the third anode 53 can be increased, so that an orthographic projection of a compensation part 82 of a second anode 52 and an orthographic projection of a compensation part 83 of a third anode 53 are at least partially overlapped with an orthographic projection of a first connection electrode 41 on the base substrate, a parasitic capacitance of a first sub-pixel column is increased, a difference between parasitic capacitance of a first sub-pixel column and a parasitic capacitance of a second sub-pixel column is reduced, so that the parasitic capacitance of the first sub-pixel column is substantially the same as the parasitic capacitance of the second sub-pixel column, which effectively eliminates vertical display defects and improves display quality and display effect.

In the related art, in a case that sizes of a first anode 51 and a corresponding pixel opening 61 and a first light emitting layer 91 in the first direction X are not contracted, and compensation of an anode compensation part reaches a compensation limit, since a size of the first anode 51 in the first direction X is relatively great, there is still a difference of about 36.17% between parasitic capacitances generated by a second anode 52 of a first sub-pixel column and a second anode 52 of a second sub-pixel column and corresponding circuit units thereof. But in an embodiment of the present disclosure, sizes of a first anode 51 and a corresponding pixel opening 61 in the first direction X are contracted, a compensation space of the second anode 52 is increased, the difference in parasitic capacitances generated by the second anode 52 of the first sub-pixel column and the second anode 52 of the second sub-pixel column and the corresponding circuit units thereof is reduced to approximately 10.57%, and the difference is reduced by approximately 25.6%, which improves the display effect to a great extent.

In an embodiment of the present disclosure, a corresponding pixel opening 61 of a first sub-pixel P1 may be set to be the same as a change of size and shape of a light emitting layer 91 of the first sub-pixel P1, for example, a shape and side length size of the pixel opening 61 of the first sub-pixel P1 may be set to be consistent with those of the light emitting layer 91.

In an implementation of the present disclosure, as shown in FIG. 15J, in order to keep areas of a first anode 51 main body part and a corresponding pixel opening 61 and a light emitting layer 91 unchanged before and after contraction is performed, sizes of the first anode 51, the corresponding pixel opening 61, and the light emitting layer 91 in the second direction Y can be increased when sizes in the first direction X are contracted. In FIG. 15J, contour 51-01 is a contour of the first anode main body part without contraction and contour 91-01 is a contour of the light emitting layer 91 of the first light emitting unit without contraction. In an embodiment of the present disclosure, sizes in the second direction Y are appropriately increased (i.e., sizes in the second direction Y are expanded), other anode compensation parts would not be sheltered, and it is ensured that when sizes of the first anode 51 main body part and the pixel opening 61 of the first light emitting unit and the first light emitting layer 91 of the first light emitting unit in the first direction X are contracted, areas of the first anode 51 main body part and the light emitting layer 91 of the first light emitting unit are substantially the same as areas of those when no contraction is performed on these sizes.

In an implementation of the present disclosure, the first anode 51 main body part and the pixel opening 61 of the first light emitting unit and the first light emitting layer 91 of the first light emitting unit can be contracted unilaterally in the first direction X. For example, after a first edge D1 is contracted, a distance between the first edge D1 and a vertex of a first included angle f1 is h2, and a distance between a second edge D2 and a vertex of the second included angle f2 is not contracted. Or, only the second edge D2 is contracted, and the first edge D1 is not contracted. Whether sizes of the first anode 51 main body part and the pixel opening 61 of the first light emitting unit and the first light emitting layer 91 of the first light emitting unit in the first direction X are contracted unilaterally or bilaterally depends on an influence of the first anode 51 on the second anode 52 or an influence of the first anode 51 on the third anode 53.

In an exemplary implementation, on a plane perpendicular to the display substrate, the drive circuit layer includes a semiconductor layer, a first conductive layer, a second conductive layer and a third conductive layer that are sequentially provided on a base substrate; the semiconductor layer at least includes an active layer of the compensation transistor T2, the first conductive layer at least includes a first plate of the storage capacitor and a gate electrode of the compensation transistor T2, and the second conductive layer at least includes a second plate of the storage capacitor, and the third conductive layer at least includes the first connection electrode 41.

FIG. 7 is a schematic diagram of a structure of a display substrate according to an exemplary embodiment of the present disclosure. In an exemplary implementation, the display substrate may include a drive circuit layer provided on a base substrate, and a light emitting structure layer provided on a side of the drive circuit layer away from the base substrate. As shown in FIG. 7, on a plane parallel to the display substrate, the drive circuit layer may include multiple circuit units constituting multiple unit rows and multiple unit columns, the light emitting structure layer may include multiple light emitting units constituting multiple sub-pixel rows and multiple sub-pixel columns, at least one circuit unit may at least include a pixel drive circuit, and at least one light emitting unit may at least include an anode, and the anode is connected to a corresponding pixel drive circuit.

In an exemplary implementation, the multiple unit columns may include a first unit column and a second unit column, and the multiple sub-pixel columns may include a first sub-pixel column and a second sub-pixel column. In an exemplary implementation, the first unit column and the first sub-pixel column may be an odd-numbered unit column and an odd-numbered sub-pixel column, respectively, and the second unit column and the second sub-pixel column may be an even-numbered unit column and an even-numbered sub-pixel column, respectively. In another exemplary implementation, the first unit column and the first sub-pixel column may be an even-numbered unit column and an even-numbered sub-pixel column, respectively, and the second unit column and the second sub-pixel column may be an odd-numbered unit column and an odd-numbered sub-pixel column, respectively. In the following description of an embodiment of the present disclosure, illustration is made by taking a case in which the first unit column and the first sub-pixel column are respectively an odd-numbered unit column and an odd-numbered sub-pixel column, and the second unit column and the second sub-pixel column are respectively an even-numbered unit column and an even-numbered sub-pixel column, as an example, the odd-numbered unit columns and odd-numbered sub-pixel columns may include a Nth column, a (N+2)th column, a (N+4)th column, a (N+6)th column, and a (N+8)th column, and the even-numbered unit columns and even-numbered sub-pixel columns may include a (N+1)th column, a (N+3)th column, a (N+5)th column, and a (N+7)th column.

In an exemplary implementation, a pixel drive circuit of the circuit unit may at least include a compensation transistor and a storage capacitor 40, and a first electrode of the compensation transistor T2 is connected to a first plate of the storage capacitor 40 through a first connection electrode 41.

In an exemplary implementation, an orthographic projection of an anode 50 of at least one light emitting unit in the first sub-pixel column on the base substrate has a first overlapping area with an orthographic projection of the first connection electrode 41 of at least one circuit unit in the first unit column on the base substrate, and an orthographic projection of an anode 50 of at least one light emitting unit in the second sub-pixel column on the base substrate has a second overlapping area with an orthographic projection of the first connection electrode 41 of at least one circuit unit in the second unit column on the base substrate, a ratio of the first overlapping area to the second overlapping area may be about from 0.8 to 1.2.

In an exemplary implementation, the first overlapping area may include an overlapping area between an orthographic projection of an anode compensation part 80 on the base substrate and an orthographic projection of an electrode main body part 41-1 and an electrode compensation part 41-2 on the base substrate, and the second overlapping area may include an overlapping area between an orthographic projection of an anode 50 on the base substrate and an orthographic projection of a first connection electrode 41 on the base substrate, and a ratio of the first overlapping area to the second overlapping area may be about from 0.9 to 1.1.

In an exemplary implementation, on a plane perpendicular to the display substrate, the drive circuit layer may include a semiconductor layer, a first conductive layer, a second conductive layer and a third conductive layer that are sequentially provided on the base substrate; the semiconductor layer at least includes active layers of multiple transistors in the pixel drive circuit, the first conductive layer at least includes the first plate of the storage capacitor and gate electrodes of the multiple transistors, and the second conductive layer at least includes the second plate of the storage capacitor, and the third conductive layer at least includes the first connection electrode 41.

In an exemplary implementation, the drive circuit layer may include a first insulation layer, a second insulation layer, a third insulation layer, a fourth insulation layer, and a planarization layer. The first insulation layer is provided between the base substrate and the semiconductor layer, the second insulation layer is provided between the semiconductor layer and the first conductive layer, the third insulation layer is provided between the first conductive layer and the second conductive layer, the fourth insulation layer is provided between the second conductive layer and the third conductive layer, and the planarization layer is provided between the third conductive layer and the anode.

Exemplary description is made below through a manufacturing process of a display substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a size of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary implementation, the manufacturing for the display substrate may at least include manufacturing a drive circuit layer and manufacturing a light emitting structure layer.

In an exemplary implementation, taking 18 circuit units (2 unit rows and 9 unit columns) as an example, the manufacturing process of the drive circuit layer may include the following acts.

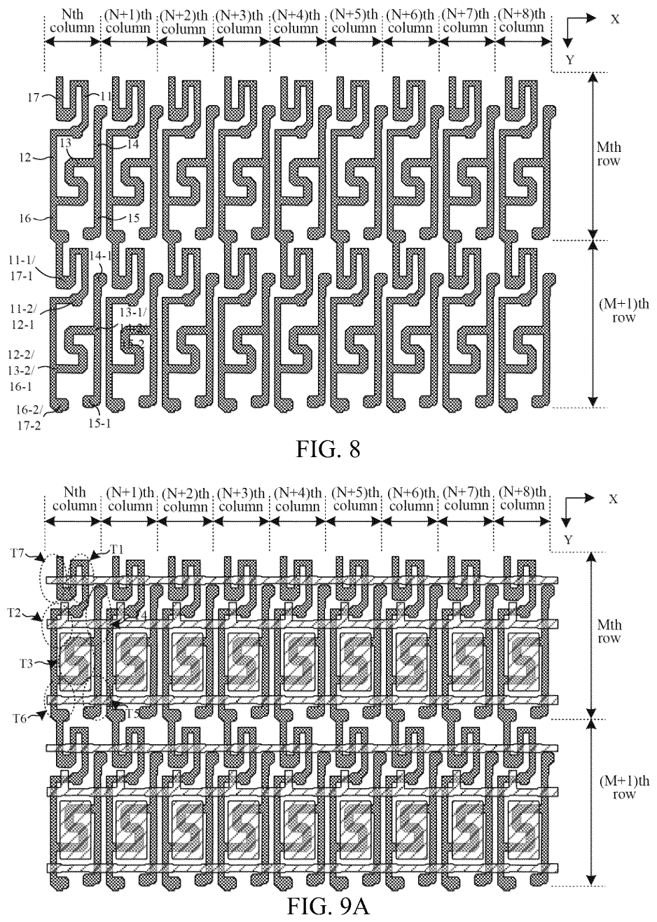

(1) A pattern of a semiconductor layer is formed. In an exemplary implementation, forming the pattern of the semiconductor layer may include: depositing sequentially a first insulation thin film and a semiconductor thin film on a base substrate, and patterning the semiconductor thin film through a patterning process to form a first insulation layer that covers the base substrate and the semiconductor layer provided on the first insulation layer, as shown in FIG. 8.

In an exemplary implementation, the semiconductor layer of each circuit unit may at least include a first active layer 11 of a first transistor T1 to a seventh active layer 17 of a seventh transistor T7. The first active layer 11 to the seventh active layer 17 are interconnected to form an integral structure, and a sixth active layer 16 of a circuit unit in a Mth row and a seventh active layer 17 of a circuit unit in a (M+1)th row in each unit column are interconnected to form an integral structure, i.e., the semiconductor layers of adjacent circuit units in each unit column are interconnected to form an integral structure.

In an exemplary implementation, in the first direction X, the fourth active layer 14 and the fifth active layer 15 in a circuit unit in the Nth column may be located on a side of the third active layer 13 of the present circuit unit close to the circuit unit in the (N+1)th column, and the second active layer 12 and the sixth active layer 16 may be located on a side of the third active layer 13 of the present circuit unit away from the circuit unit in the (N+1)th column.

In an exemplary implementation, in the second direction Y, the first active layer 11, the second active layer 12, the fourth active layer 14, and the seventh active layer 17 in a circuit unit in the Mth row may be located on a side of the third active layer 13 of the present circuit unit away from the circuit unit in the (M+1)th row, the first active layer 11 and the seventh active layer 17 may be located on a side of the second active layer 12 and the fourth active layer 14 away from the third active layer 13, and the fifth active layer 15 and the sixth active layer 16 in the circuit unit in the Mth row may be located on a side of the third active layer 13 close to the circuit unit in the (M+1)th row.

In an exemplary implementation, the first active layer 11 may have an “n” shape, the third active layer 13 may have an “S” shape, the second active layer 12 may have an “L” shape, and the fourth active layer 14, the fifth active layer 15, the sixth active layer 16 and the seventh active layer 17 may have an “I” shape.

In an exemplary implementation, an active layer of each transistor may include a first region, a second region, and a channel region located between the first region and the second region. In an exemplary implementation, a first region 11-1 of the first active layer 11 may serve as a first region 17-1 of the seventh active layer 17; a second region 11-2 of the first active layer 11 may serve as a first region 12-1 of the second active layer 12; a first region 13-1 of the third active layer 13 may serve as a second region 14-2 of the fourth active layer 14 and a second region 15-2 of the fifth active layer 15 simultaneously; a second region 13-2 of the third active layer 13 may serve as a second region 12-2 of the second active layer 12 and a first region 16-1 of the sixth active layer 16 simultaneously; a second region 16-2 of the sixth active layer 16 may serve as a second region 17-2 of the seventh active layer 17 simultaneously; and a first region 14-1 of the fourth active layer 14 and a first region 15-1 of the fifth active layer 15 are separately provided.

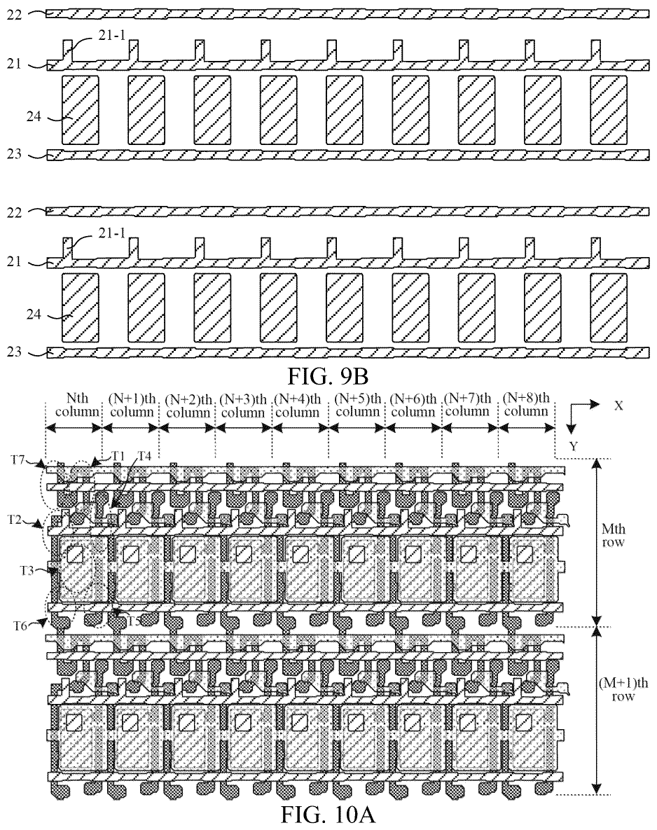

(2) A pattern of a first conductive layer is formed. In an exemplary implementation, forming the pattern of the first conductive layer may include: depositing sequentially a second insulation thin film and a first conductive thin film on the base substrate on which the aforementioned patterns are formed, and patterning the first conductive thin film through a patterning process to form a second insulation layer that covers a pattern of the semiconductor layer and form the pattern of the first conductive layer provided on the second insulation layer, as shown in FIG. 9A and FIG. 9B, and FIG. 9B is a planar schematic diagram of the first conductive layer in FIG. 9A. In an exemplary implementation, the first conductive layer may be called a first gate metal (GATE1) layer.

In an exemplary implementation, the pattern of the first conductive layer of each circuit unit may at least include a first scan signal line 21, a second scan signal line 22, a light emitting control signal line 23, and a first plate 24.

In an exemplary implementation, the first plate 24 of the storage capacitor may have a rectangular shape, and chamfers may be provided at corners of the rectangle. An orthographic projection of the first plate 24 on the base substrate is at least partially overlapped with an orthographic projection of a third active layer of a third transistor T3 on the base substrate. In an exemplary implementation, the first plate 24 may serve as a plate of the storage capacitor and a gate electrode of the third transistor T3 simultaneously.

In an exemplary implementation, the first scan signal line 21, the second scan signal line 22, and the light emitting control signal line 23 may be of a line shape in which a main body portion extends along the first direction X, the first scan signal line 21 in circuit units of the Mth row may be located on a side of the first plate 24 of the present circuit unit away from the circuit units of the (M+1)th row, the second scan signal line 22 may be located on a side of the first scan signal line 21 away from the first plate 24, and the light emitting control signal line 23 may be located on a side of the first plate 24 of the present circuit unit close to the circuit units of the (M+1)th row.

In an exemplary implementation, a gate block 21-1 is provided on a side of the first scan signal line 21 away from the first plate 24, a region in which the first scan signal line 21 and the gate block 21-1 are overlapped with the second active layer 12 serves as a gate electrode of the second transistor T2 with a double-gate structure, and a region in which the first scan signal line 21 is overlapped with the fourth active layer 14 serves as a gate electrode of the fourth transistor T4.

In an exemplary implementation, a region in which the second scan signal line 22 is overlapped with the first active layer 11 serves as a gate electrode of the first transistor T1 with a double-gate structure, a region in which the second scan signal line 22 is overlapped with the seventh active layer 17 serves as a gate electrode of the seventh transistor T7, a region in which the light emitting control signal line 23 is overlapped with the fifth active layer 15 serves as a gate electrode of the fifth transistor T5, and a region in which the light emitting control signal line 23 is overlapped with the sixth active layer 16 serves as a gate electrode of the sixth transistor T6.

In an exemplary implementation, after the pattern of the first conductive layer is formed, a conductive processing may be performed on the semiconductor layer by using the first conductive layer as a shelter, the semiconductor layer in a region sheltered by the first conductive layer forms channel regions of the first transistor T1 to the seventh transistor T7, and the semiconductor layer in a region not sheltered by the first conductive layer is made to be conductive, i.e., first regions and second regions of the first active layer to the seventh active layer are all made to be conductive.

(3) A pattern of a second conductive layer is formed. In an exemplary implementation, forming a pattern of a second conductive layer may include: depositing sequentially a third insulation thin film and a second conductive thin film on the base substrate on which the aforementioned patterns are formed, and the second conductive thin film is patterned through a patterning process to form a third insulation layer that covers the first conductive layer and the pattern of the second conductive layer provided on the third insulation layer, as shown in FIG. 10A and FIG. 10B. FIG. 10B is a planar schematic diagram of the second conductive layer in FIG. 10A. In an exemplary implementation, the second conductive layer may be called a second gate metal (GATE2) layer.

In an exemplary implementation, the pattern of the second conductive layer of each circuit unit may at least include an initial signal line 31, a second plate 32, a plate connection line 33, and a shielding electrode 34.

In an exemplary implementation, the initial signal line 31 may have a line shape in which a main body portion extends along the first direction X. The initial signal line 31 in the circuit units in the Mth row may be located on a side of the second scan signal line 22 away from the first scan signal line 21, and the initial signal line 31 is configured to provide an initial voltage signal to the first transistor T1 and the seventh transistor T7.

In an exemplary implementation, a contour of the second plate 32 of the storage capacitor may be a rectangular shape, corners of which may be provided with chamfers. An orthographic projection of the second plate 32 on the base substrate is at least partially overlapped with an orthographic projection of the first plate 24 on the base substrate, and the first plate 24 and the second plate 32 form the storage capacitor of the pixel drive circuit.

In an exemplary implementation, the plate connection line 33 may be provided on a side of the second plate 33 in the first direction X or an opposite direction of the first direction X, a first end of the plate connection line 33 is connected to the second plate 32 of the present circuit unit, and a second end of the plate connection line 33 is connected to a second plate 32 of an adjacent circuit unit in a circuit row after extending along the first direction X or the opposite direction of the first direction X, so that second plates 32 of adjacent circuit units on a unit row are connected to each other through the plate connection line 33. In an exemplary implementation, the second plate 32 is connected to a first voltage line to be formed sequentially, the plate connection line 33 enables second plates of multiple circuit units in a unit row to be interconnected to form an integral structure, and the second plate of the integral structure may be multiplexed as a power supply signal line, which ensures that multiple second plates in a unit row have a same potential, which is beneficial to improve uniformity of a panel, avoiding display defect of the display substrate and ensuring a display effect of the display substrate.

In an exemplary implementation, an opening 35 is provided on the second plate 32 and may be located in a middle part of the second plate 32, and a shape of the opening 35 may be a rectangle, so that the second plate 32 forms an annular structure. The opening 35 exposes the third insulation layer covering the first plate 24, and an orthographic projection of the first plate 24 on the base substrate contains an orthographic projection of the opening 35 on the base substrate. In an exemplary implementation, the opening 35 is configured to accommodate a first via to be formed subsequently, and the first via is located within the opening 35 and exposes the first plate 24, so that a second electrode of the first transistor T1 to be formed subsequently is connected to the first plate 24.

In an exemplary implementation, the shielding electrode 34 may be located between the first scan signal line 21 (excluding the main body portion of the gate block 21-1) and the second scan signal line 22 of the present circuit unit, a shape of the shielding electrode 34 may be an “L” shape, an orthographic projection of the shielding electrode 34 on the base substrate is at least partially overlapped with an orthographic projection of the second region of the first active layer on the base substrate, the orthographic projection of the shielding electrode 34 on the base substrate is at least partially overlapped with an orthographic projection of the first region of the second active layer on the base substrate, and the shielding electrode 34 is configured to shield an influence of a data voltage jump on a key node, prevent the data voltage jump from affecting a potential of the key node of the pixel drive circuit, and improve the display effect.

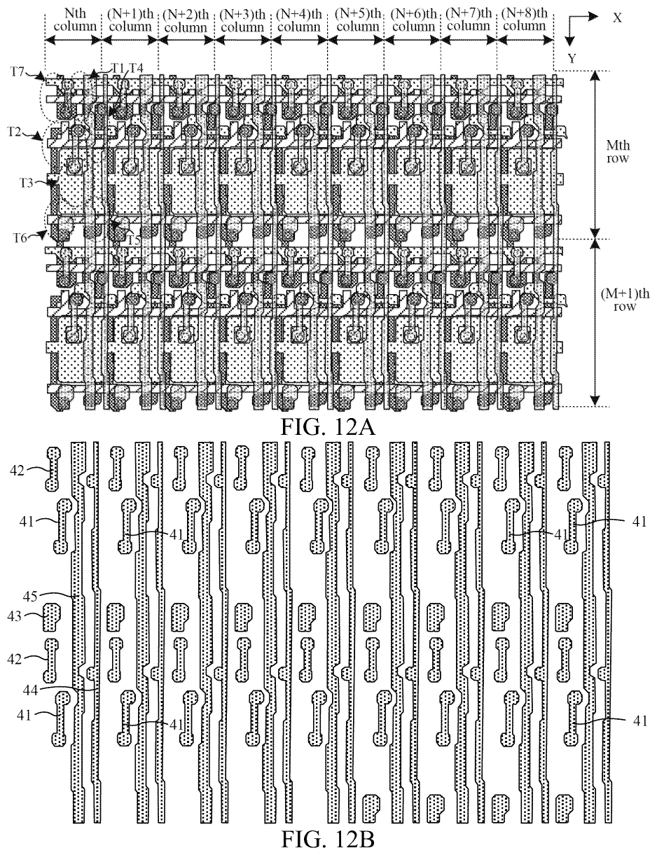

(4) A pattern of a fourth insulation layer is formed. In an exemplary implementation, forming the pattern of the fourth insulation layer may include: depositing a fourth insulation thin film on the base substrate on which the aforementioned patterns are formed, and patterning the fourth insulation thin film through a patterning process to form a fourth insulation layer that covers the second conductive layer, wherein multiple vias are provided on each circuit unit, as shown in FIG. 11.

In an exemplary implementation, the multiple vias of each circuit unit may at least include a first via V1, a second via V2, a third via V3, a fourth via V4, a fifth via V5, a sixth via V6, a seventh via V7, an eighth via V8 and a ninth via V9.

In an exemplary implementation, an orthographic projection of the first via V1 on the base substrate is located within a range of an orthographic projection of the opening 35 of the second plate 32 on the base substrate, the fourth insulation layer and the third insulation layer within the first via V1 are etched away to expose a surface of the first plate 24, and the first via V1 is configured such that the second electrode of the first transistor T1 to be formed subsequently is connected to the first plate 24 through the first via V1.

In an exemplary implementation, an orthographic projection of the second via V2 on the base substrate is within a range of an orthographic projection of the second plate 32 on the base substrate, the fourth insulation layer within the second via V2 is etched away to expose a surface of the second plate 32, and the second via V2 is configured such that a first power supply line to be formed subsequently is connected to the second plate 32 through the second via V2. In an exemplary implementation, the second via V2 may be plural, and multiple second vias V2 may be sequentially arranged in the second direction Y, thereby increasing the connection reliability between the first power supply line and the second plate 32.

In an exemplary implementation, an orthographic projection of the third via V3 on the base substrate is within a range of an orthographic projection of the first region of the fifth active layer on the base substrate. The fourth insulation layer, the third insulation layer, and the second insulation layer within the third via V3 are etched away to expose a surface of the first region of the fifth active layer, and the third via V3 is configured such that the first power supply line to be formed subsequently is connected to the first region of the fifth active layer through the third via V3.

In an exemplary embodiment, an orthographic projection of the fourth via V4 on the base substrate is within a range of an orthographic projection of the second region of the sixth active layer (also the second region of the seventh active layer) on the base substrate. The fourth insulation layer, the third insulation layer, and the second insulation layer in the fourth via V4 are etched away to expose a surface of the second region of the sixth active layer, the fourth via V4 is configured such that the second electrode of the sixth transistor T6 (also the second electrode of the seventh transistor T7) to be formed subsequently is connected to the second region of the sixth active layer (also the second region of the seventh active layer) through the fourth via V4.

In an exemplary implementation, an orthographic projection of the fifth via V5 on the base substrate is within a range of an orthographic projection of the first region of the fourth active layer on the base substrate. The fourth insulation layer, the third insulation layer, and the second insulation layer in the fifth via V5 are etched away to expose a surface of the first region of the fourth active layer, and the fifth via V5 is configured such that the data signal line to be formed subsequently is connected to the first region of the fourth active layer through the fifth via V5.

In an exemplary implementation, an orthographic projection of the sixth via V6 on the base substrate is within a range of an orthographic projection of the second region of the first active layer (also the first region of the second active layer) on the base substrate. The fourth insulation layer, the third insulation layer, and the second insulation layer in the sixth via V6 are etched away to expose a surface of the second region of the first active layer, the sixth via V6 is configured such that the second electrode of the first transistor T1 to be formed subsequently (also the first electrode of the second transistor T2) is connected to the second region of the first active layer (also the first region of the second active layer) through the sixth via V6.

In an exemplary implementation, an orthographic projection of the seventh via V7 on the base substrate is within a range of an orthographic projection of the first region of the first active layer (also the first region of the seventh active layer) on the base substrate. The fourth insulation layer, the third insulation layer, and the second insulation layer in the seventh via V7 are etched away to expose a surface of the first region of the first active layer, the seventh via V7 is configured such that the first electrode of the first transistor T1 to be formed subsequently (also the first electrode of the seventh transistor T7) is connected to the first region of the first active layer (also the first region of the seventh active layer) through the seventh via V7.

In an exemplary implementation, an orthographic projection of the eighth via V8 on the base substrate is within a range of an orthographic projection of the shielding electrode 34 on the base substrate. The fourth insulation layer in the eighth via V8 is etched away to expose a surface of the shielding electrode 34, and the eighth via V8 is configured such that the first power supply line to be formed subsequently is connected to the shielding electrode 34 through the eighth via V8.

In an exemplary implementation, an orthographic projection of the ninth via V9 on the base substrate is within a range of an orthographic projection of the initial signal line 31 on the base substrate, the fourth insulation layer in the ninth via V9 is etched away to expose a surface of the initial signal line 31, and the ninth via V9 is configured such that the first electrode (also the first electrode of the second transistor T7) of the first transistor T1 to be formed subsequently is connected to the initial signal line 31 through the ninth via V9.

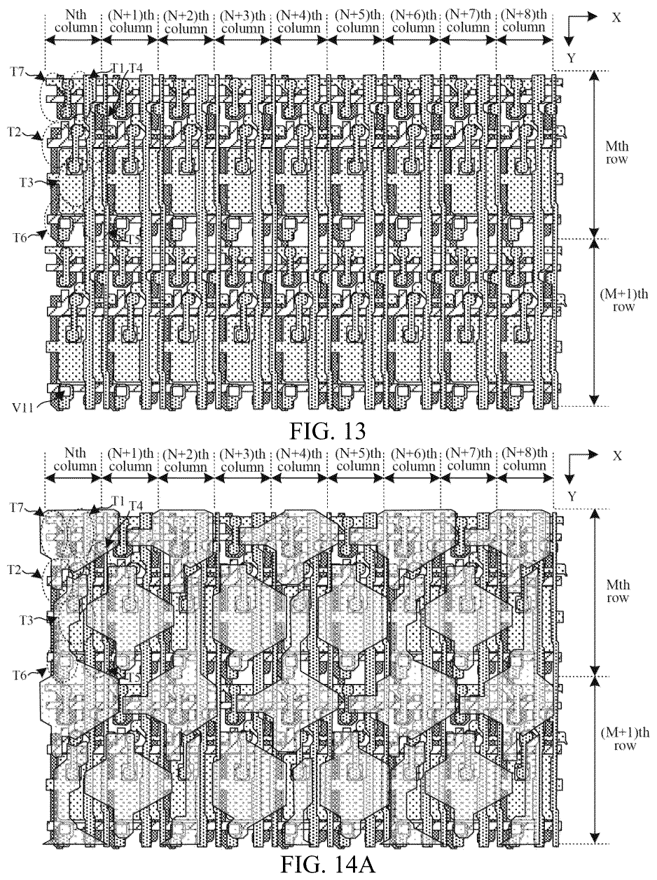

(5) A pattern of a third conductive layer is formed. In an exemplary implementation, forming the third conductive layer may include: depositing a third conductive thin film on the base substrate on which the aforementioned patterns are formed, and patterning the third conductive thin film by a patterning process to form the third conductive layer provided on the fourth insulation layer, as shown in FIG. 12A and FIG. 12B, and FIG. 12B is a planar schematic diagram of the third conductive layer in FIG. 12A. In an exemplary implementation, the third conductive layer may be referred to as a first source-drain metal (SD1) layer.

In an exemplary implementation, the third conductive layer of each circuit unit at least includes a first connection electrode 41, a second connection electrode 42, a third connection electrode 43, a data signal line 44, and a first power supply line 45.

In an exemplary implementation, the first connection electrode 41 may be a strip shape extending along the second direction Y. The first connection electrode 41 is connected to the first plate 24 and the second region of the first active layer (also the first region of the second active layer) through the first via V1 and the sixth via V6 respectively, so that the first plate 24, the second electrode of the first transistor T1 and the first electrode of the second transistor T2 have a same potential. In an exemplary implementation, the first connection electrode 41 may simultaneously serve as the second electrode of the first transistor T1 and the first electrode of the second transistor T2 (the second node N2 of the pixel drive circuit).

In an exemplary implementation, a shape of the second connection electrode 42 may be a strip shape extending along the second direction Y, a first end of the second connection electrode 42 is connected to the first region (also the first region of the seventh active layer) of the first active layer through the seventh via V7, and a second end of the second connection electrode 42 is connected to the initial signal line 31 through the ninth via V9, which makes the initial signal line 31 write an initial voltage signal into the first transistor T1 and the seventh transistor T7. In an exemplary implementation, the second connection electrode 42 may serve as the first electrode of the first transistor T1 and the first electrode of the seventh transistor T7 simultaneously.

In an exemplary implementation, a shape of the third connection electrode 43 may be a polygon shape, and the third connection electrode 43 is connected to the second region (also the second region of the seventh active layer) of the sixth active layer through the fourth via V4, which makes the second electrode of the sixth transistor T6 and the second electrode of the seventh transistor T7 have a same potential. In an exemplary implementation, the third connection electrode 43 may serve as the second electrode of the sixth transistor T6 and the second electrode of the seventh transistor T7 simultaneously, and the third connection electrode 43 serves as an anode connection electrode and is configured to be connected to an anode to be formed subsequently.

In an exemplary implementation, a shape of the data signal line 44 may have a line shape in which a main body portion extends along the second direction Y, and the data signal line 44 is connected to a first region of the fourth active layer through the fifth via V5, achieving that the data signal line 44 writes a data signal into the fourth transistor T4.

In an exemplary implementation, the first power supply line 45 may have a polyline shape in which a main body portion of the first power supply line 45 extends along the second direction Y. On one aspect, the first power supply line 45 is connected to the second plate 32 through the second via V2, on another aspect, the first power supply line 45 is connected to the first region of the fifth active layer through the third via V3, and on yet another aspect, the first power supply line 45 is connected to the shielding electrode 34 through the eighth via V8, thereby achieving that the first power supply line 45 writes the first power supply signal into the fifth transistor T5, and the second plate 32 and the shielding electrode 34 have a same potential as the first power supply line 45.

In an exemplary implementation, since an orthographic projection of a strip part of the shielding electrode 34 on the base substrate is at least partially overlapped with an orthographic projection of the first region of the second active layer on the base substrate, and the strip part of the shielding electrode 34 extending along the second direction Y is located between the first connection electrode 41 and the data signal line 44 and connected to the first power supply line 45 through the shielding electrode 34, and the shielding electrode 34 is a constant voltage signal, the shielding electrode 34 can effectively shield an influence of the data voltage jump of the data signal line 44 on the second node N2 in the pixel drive circuit, prevent the data voltage jump from affecting the potential of the key node of the pixel drive circuit, thereby improving the display effect.

In the exemplary implementation, the first connection electrode 41 and the data signal line 44 are respectively located on two sides of the first power supply line 45 in the first direction X. Since the first power supply line 45 is a constant voltage signal, it can effectively shield an influence of the data voltage jump on the second node N2 in the pixel drive circuit, and avoid an influence of the data voltage jump on the potential of the key node of the pixel drive circuit, thereby improving the display effect.

In an exemplary implementation, the first power supply line 45 of at least one circuit unit may be a polyline of non-equal width. The first power supply line 45 is set as a polyline, which not only may facilitate a layout of a pixel structure, but also may reduce parasitic capacitance between the first power supply line and the data signal line.

In an exemplary implementation, in at least one unit column, first connection electrodes 41 of at least two circuit units may have a same shape.

In an exemplary implementation, in at least one unit row, the multiple circuit units may at least include a first circuit unit, a second circuit unit, and a third circuit unit. The pixel drive circuit of the first circuit unit is connected to a red light emitting unit emitting red light, the pixel drive circuit of the second circuit unit is connected to a blue light emitting unit emitting blue light, and the pixel drive circuit of the third circuit unit is connected to a green light emitting unit emitting green light. Shapes of the first connection electrode 41 in the first circuit unit, the first connection electrode 41 in the second circuit unit, and the first connection electrode 41 in the third circuit unit may be the same or different.

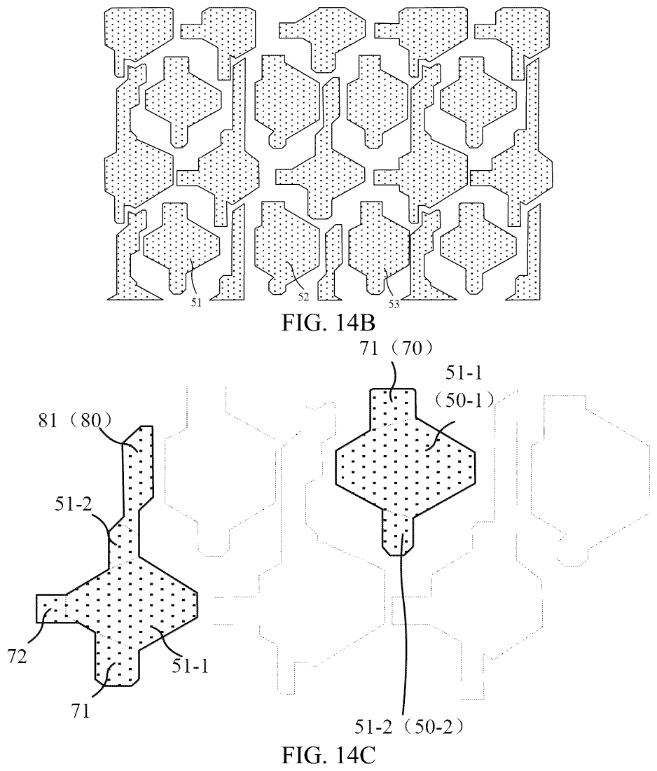

(6) A pattern of a planarization layer is formed. In an exemplary implementation, forming the pattern of the planarization layer may include: coating a planarization thin film on the base substrate on which the above patterns are formed, patterning the planarization thin film through a patterning process to form a planarization layer covering the third conductive layer, wherein multiple vias are provided on the planarization layer, as shown in FIG. 13.

In an exemplary implementation, vias in each circuit unit at least includes an eleventh via V11. An orthographic projection of the eleventh via V11 on the base substrate is located within a range of an orthographic projection of the third connection electrode 43 on the base substrate, a first planarization layer in the eleventh via V11 is removed to expose a surface of the third connection electrode 43, and the eleventh via V11 is configured such that the anode to be formed subsequently is connected to the third connection electrode 43 through the eleventh via V11.

So far, a drive circuit layer has been manufactured on the base substrate. On a plane parallel to the display substrate, the drive circuit layer may include multiple circuit units, each of the circuit units may include a pixel drive circuit, and a first scan signal line, a second scan signal line, a light emitting control signal line, an initial signal line, a data signal line, and a first power supply line connected to the pixel drive circuit. On a plane perpendicular to the display substrate, the drive circuit layer may include a first insulation layer, a semiconductor layer, a second insulation layer, a first conductive layer, a third insulation layer, a second conductive layer, a fourth insulation layer, a third conductive layer, a planarization layer which are sequentially stacked on the base substrate.

In an exemplary implementation, the base substrate may be a flexible base substrate, or a rigid base substrate. The rigid base substrate may be made of, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation, the flexible base substrate may include a first flexible material layer, a first inorganic material layer, a semiconductor layer, a second flexible material layer, and a second inorganic material layer which are stacked, wherein materials of the first flexible material layer and the second flexible material layer may be Polyimide (PI), Polyethylene Terephthalate (PET), or a surface-treated polymer soft film, or the like, materials of the first inorganic material layer and the second inorganic material layer may be Silicon Nitride (SiNx) or Silicon Oxide (SiOx), or the like, for improving a water and oxygen resistance capability of the base substrate, and a material of the semiconductor layer may be amorphous silicon (a-si).

In an exemplary implementation, the first conductive layer, the second conductive layer, and the third conductive layer may be made of a metal material, for example, any one or more of Argentum (Ag), Copper (Cu), Aluminum (Al), and Molybdenum (Mo), or an alloy material of the aforementioned metals, for example, an Aluminum-Neodymium alloy (AlNd) or a Molybdenum-Niobium alloy (MoNb), and may be in a single-layer structure, or in a multilayer composite structure such as Mo/Cu/Mo, etc. The first insulation layer, the second insulation layer, the third insulation layer, and the fourth insulation layer may be made of any one or more of Silicon Oxide (SiOx), Silicon Nitride (SiNx), and Silicon Oxynitride (SiON), and may be a single layer, a multi-layer, or a composite layer. The first insulation layer may be referred to as a buffer layer, the second insulation layer, and the third insulation layer may be referred to as Gate Insulator (GI) layers, and the fourth insulation layer may be referred to as an Interlayer Dielectric (ILD) layer. The planarization layer may be made of an organic material such as resin. An active layer may be made of a material such as amorphous Indium Gallium Zinc Oxide (a-IGZO), Zinc Oxynitride (ZnON), Indium Zinc Tin Oxide (IZTO), amorphous Silicon (a-Si), poly-crystalline Silicon (p-Si), hexathiophene, or polythiophene, i.e., the present disclosure is applicable to a transistor, i.e., manufactured based on an oxide technology, a silicon technology, or an organic matter technology.

In an exemplary implementation, after manufacturing of the drive circuit layer is completed, a light emitting structure layer is prepared on the drive circuit layer, and a preparation process of the light emitting structure layer may include following acts.

(7) A pattern of an anode conductive layer is formed. In an exemplary implementation, forming a pattern of an anode conductive layer may include: depositing an anode conductive thin film on the base substrate on which the aforementioned patterns are formed, and patterning the anode conductive thin film through a patterning process to form the pattern of the anode conductive layer provided on the planarization layer, as shown in FIG. 14A and FIG. 14B, and FIG. 14B is a planar schematic diagram of the anode conductive layer in FIG. 14A.

In an exemplary implementation, the pattern of the anode conductive layer may at least include multiple anodes, and the multiple anodes may include a first anode 51 of a red light emitting unit, a second anode 52 of a blue light emitting unit, and a third anode 53 of a green light emitting unit. A region where the first anode 51 is located may form a red light emitting unit that emits red light, a region where the second anode 52 is located may form a blue light emitting unit that emits blue light, and a region where the third anode 53 is located may form a green light emitting unit that emits green light.

In an exemplary implementation, the first anode 51, the second anode 52, and the third anode 53 may be respectively connected to the third connection electrodes 43 in the corresponding circuit units through the eleventh via V11. Because the third connection electrode 43 in the circuit unit is connected to the second region (also the second region of the seventh active layer) of the sixth active layer through a via, the first anode 51, the second anode 52 and the third anode 53 may be respectively connected to the second electrode of the sixth transistor T6 and the second electrode of the seventh transistor T7 through the third connection electrode 43, thereby achieving that the pixel drive circuit drives the light emitting device to emit light.

In an exemplary implementation, the multiple light emitting units may constitute multiple sub-pixel rows and multiple sub-pixel columns. A sub-pixel row may include multiple light emitting units provided sequentially in the first direction X, and a sub-pixel column may include multiple light emitting units provided sequentially in the second direction Y.

In an exemplary implementation, positions of multiple light emitting units of two sub-pixel rows correspond to positions of multiple pixel drive circuits of one unit row, i.e., a region of one unit row corresponds to a region of two sub-pixel rows. The first anodes 51, the second anodes 52, and the third anodes 53 in each sub-pixel row may be periodically provided in the first direction X, and the first anodes 51, the second anodes 52, and the third anodes 53 of adjacent sub-pixel rows are provided in a staggered manner.

In an exemplary implementation, positions of multiple light emitting units of one sub-pixel column correspond to positions of multiple pixel drive circuits of one unit column, i.e., a region of one unit column corresponds to a region of one sub-pixel column. Each sub-pixel column includes multiple anodes provided sequentially in the second direction Y, and multiple anodes of adjacent sub-pixel columns are provided in a staggered manner. The multiple anodes of one sub-pixel column may be multiple first anodes 51, the multiple anodes of another sub-pixel column may be multiple second anodes 52, and the multiple anodes of yet another sub-pixel column may be multiple third anodes 53.

In an exemplary implementation, in the first direction X, the first anode 51 in one sub-pixel row may be located between a second anode 52 and a third anode 53 in an adjacent sub-pixel row, the three anodes form a triangular-arranged pixel unit. In the first direction X, a second anode 52 in one sub-pixel row may be located between a third anode 53 and a first anode 51 in an adjacent sub-pixel row, and the three anodes form a triangular-arranged pixel unit. In the first direction X, a third anode 53 in one sub-pixel row may be located between a first anode 51 and a second anode 52 in an adjacent sub-pixel row, and the three anodes form a triangular-arranged pixel unit. Thus, the multiple first anodes 51, the multiple second anodes 52 and the multiple third anodes 53 form a Delta pixel arrangement.

In an exemplary implementation, in the second direction Y, the first anode 51 in one sub-pixel column may be located between two second anodes 52 in an adjacent sub-pixel column, the first anode 51 in one sub-pixel column may be located between two third anodes 53 in another adjacent sub-pixel column, and one first anode 51, two second anodes 52, and two third anodes 53 may form four triangular-arranged pixel units. In the second direction Y, the second anode 52 in one sub-pixel column may be located between two first anodes 51 in an adjacent sub-pixel column, the second anode 52 in one sub-pixel column may be located between two third anodes 53 in another adjacent sub-pixel column, and two first anodes 51, one second anode 52, and two third anodes 53 may form four triangular-arranged pixel units. In the second direction Y, the third anode 53 in one sub-pixel column may be located between two second anodes 52 in an adjacent sub-pixel column, the third anode 53 in one sub-pixel column may be located between two first anodes 51 in another adjacent sub-pixel column, and two first anodes 51, two second anodes 52, and one third anode 53 may form four triangular-arranged pixel units.

In an exemplary implementation, shapes and areas of the first anode 51, the second anode 52 and the third anode 53 may be different.

In an exemplary implementation, the multiple sub-pixel rows may include a first sub-pixel row and a second sub-pixel row. The first anode 51 in the first sub-pixel row and the first anode 51 in the second sub-pixel row may have different shapes and areas, the second anode 52 in the first sub-pixel row and the second anode 52 in the second sub-pixel row may have different shapes and areas, and the third anode 53 in the first sub-pixel row and the third anode 53 in the second sub-pixel row may have different shapes and areas.

In an exemplary implementation, the anode conductive layer may be of a single-layer structure, such as Indium Tin Oxide (ITO) or Indium Zinc Oxide (IZO), or may be of a multi-layer composite structure, such as ITO/Ag/ITO.

FIG. 14C is a planar schematic diagram of a first anode according to an exemplary embodiment of the present disclosure, FIG. 14D is a planar schematic diagram of a second anode according to an exemplary embodiment of the present disclosure, and FIG. 14E is a planar schematic diagram of a third anode according to an exemplary embodiment of the present disclosure. In an exemplary implementation, an anode of the first sub-pixel column may include an anode compensation part 50-2.

As shown in FIG. 14C, the first anode 51 may include a first anode main body part 51-1 and a first anode connection part 51-2, a shape of the first anode main body part 51-1 may be a hexagon-like shape, a shape of the first anode connection part 51-2 may be a strip shape extending along the second direction Y and is connected to the first anode main body part 51-1, and the first anode connection part 51-2 is configured to be connected to a corresponding third connection electrode 43 through the eleventh via V11.

In an exemplary implementation, a first anode connection part 51-2 of an odd-numbered sub-pixel column may be provided on a side of the first anode main body part 51-1 in an opposite direction of the second direction Y, and a first anode connection part 51-2 of an even-numbered sub-pixel column may be provided on a side of the first anode main body part 51-1 in the second direction Y.

In an exemplary implementation, the first anode 51 may further include a first protrusion part 71, wherein a shape of the first protrusion part 71 may be a strip shape extending along the second direction Y, a first end of the first protrusion part 71 is connected to the first anode main body part 51-1, and a second end of the first protrusion part 71 extends towards a direction away from the first anode main body part 51-1.

In an exemplary implementation, the first protrusion part 71 may be provided on a side of the first anode main body part 51-1 away from the first anode connection part 51-2. For example, a first protrusion part 71 of an odd-numbered sub-pixel column may be provided on a side of the first anode main body part 51-1 in the second direction Y, and a first protrusion part 71 of an even-numbered sub-pixel column may be provided on a side of the first anode main body part 51-1 in an opposite direction of the second direction Y.

In an exemplary implementation, an orthographic projection of the first protrusion part 71 on the base substrate is at least partially overlapped with an orthographic projection of the first scan signal line 21 and the gate block 21-1 on the base substrate, and the first protrusion part 71 is configured to shield the second transistor T2, so as to improve the electrical performance of the second transistor T2, and improve the display quality and display effect.

In an exemplary implementation, a first anode 51 in an odd-numbered sub-pixel column may also include a second protrusion part 72. A shape of the second protrusion part 72 may be s strip shape extending along the first direction X, a first end of the second protrusion part 72 is connected to a first anode main body part 51-1, and a second end of the second protrusion part 72 extends along a direction away from the first anode main body part 51-1.

In an exemplary implementation, the second protrusion part 72 may be provided on a side of the first anode main body part 51-1 in an opposite direction of the first direction X, an orthographic projection of the second protrusion part 72 on the base substrate is at least partially overlapped with an orthographic projection of the second connection electrode 42 and the first power supply line 45 in the circuit unit in the previous column on the base substrate, and the second protrusion part 72 is configured to adjust flatness of the first anode 51 of the odd-numbered sub-pixel column so that wires of the third conductive layer below the anode are as symmetrical as possible, which reduces brightness differences and improves the display quality and display effect.

In an exemplary implementation, the first anode 51 in the even-numbered sub-pixel column may not be provided with the second protrusion part 72.

In an exemplary implementation, the first anode 51 in the odd-numbered sub-pixel column may include a first anode compensation part 81, an orthographic projection of the anode main body part of the first anode 51 of the odd-numbered sub-pixel column on the base substrate is not overlapped with an orthographic projection of the first connection electrode on the base substrate, and the first anode compensation part 81 is configured so that a parasitic capacitance of the odd-numbered sub-pixel column and a parasitic capacitance of the even-numbered sub-pixel column are substantially the same.

In an exemplary implementation, the first anode compensation part 81 may have a polyline shape extending along the second direction Y, a first end of the first anode compensation part 81 is connected to the first anode connection part 51-2, and a second end of the first anode compensation part 81 extends along a direction away from the first anode main body part 51-1 (an opposite direction of the second direction Y).

In an exemplary implementation, an orthographic projection of the first anode compensation part 81 on the base substrate is at least partially overlapped with the orthographic projection of the first connection electrode 41 on the base substrate. Since the first connection electrode 41 has a potential of the second node N2 in the pixel drive circuit and the first anode compensation part 81 has a potential of the fourth node N4 in the pixel drive circuit, the first anode compensation part 81 and the first connection electrode 41 may form a parasitic capacitor.

In an exemplary implementation, a first anode in an even-numbered sub-pixel column may not include a first anode compensation part, and an orthographic projection of the anode main body part of the first anode of the even-numbered sub-pixel column on the base substrate is at least partially overlapped with an orthographic projection of the first connection electrode on the base substrate.

In an exemplary implementation, the first anode main body part 51-1, the first anode connection part 51-2, the first protrusion part 71, the second protrusion part 72, and the first anode compensation part 81 of the odd-numbered sub-pixel column may be interconnected to form an integral structure, and the first anode main body part 51-1, the first anode connection part 51-2, and the first protrusion part 71 of the even-numbered sub-pixel column may be interconnected to form an integral structure.

In an exemplary implementation, a first overlapping area may include an overlapping area of an orthographic projection of the first anode compensation part on the base substrate and the orthographic projection of the first connection electrode on the base substrate, a second overlapping area may include an overlapping area of an orthographic projection of the first anode compensation part on the base substrate and the orthographic projection of the first connection electrode on the base substrate, an orthographic projection of the first anode compensation part of at least one light emitting unit in an odd-numbered sub-pixel column on the base substrate and the orthographic projection of the first connection electrode on the base substrate have the first overlapping area, an orthographic projection of the first anode main body part of at least one light emitting unit in an even-numbered sub-pixel column on the base substrate and the orthographic projection of the first connection electrode on the base substrate have the second overlapping area, and a ratio of the first overlapping area to the second overlapping area may be about from 0.8 to 1.2.

As shown in FIG. 14D, the second anode 52 may include a second anode main body part 52-1 and a second anode connection part 52-2, a shape of the second anode main body part 52-1 may be a hexagon-like shape, a shape of the second anode connection part 52-2 may be a strip shape extending along the second direction Y and is connected to the second anode main body part 52-1, and the second anode connection part 52-2 is configured to be connected to a corresponding third connection electrode 43 through the eleventh via V11.

In an exemplary implementation, a second anode connection part 52-2 of an odd-numbered sub-pixel column may be provided on a side of the second anode main body part 52-1 in an opposite direction of the second direction Y, and a second anode connection part 52-2 of an even-numbered sub-pixel column may be provided on a side of the second anode main body part 52-1 in the second direction Y.

In an exemplary implementation, the second anode 52 may further include a third protrusion part 73, a shape of the third protrusion part may be a strip shape extending along the second direction Y, a first end of the third protrusion part is connected to the second anode main body part 52-1, and a second end of the third protrusion part 73 extends along a direction away from the second anode main body part 52-1.

In an exemplary implementation, the third protrusion part 73 may be provided on a side of the second anode main body part 52-1 away from the second anode connection part 52-2. For example, a third protrusion part 73 of an odd-numbered sub-pixel column may be provided on a side of the second anode main body part 52-1 in the second direction Y, and a third protrusion part 73 of an even-numbered sub-pixel column may be provided on a side of the second anode main body part 52-1 in an opposite direction of the second direction Y.

In an exemplary implementation, an orthographic projection of the third protrusion part 73 on the base substrate is at least partially overlapped with an orthographic projection of the first scan signal line 21 and the gate block 21-1 on the base substrate, and the third protrusion part 73 is configured to shield the second transistor T2, so as to improve the electrical performance of the second transistor T2, and improve the display quality and display effect.

In an exemplary implementation, a second anode 52 of an odd-numbered sub-pixel column may also include a fourth protrusion part 74. A shape of the fourth protrusion part 74 may be a strip shape extending along the first direction X, a first end of the fourth protrusion part 74 is connected to the second anode main body part 52-1, and a second end of the fourth protrusion part 74 extends along a direction away from the second anode main body part 52-1.

In an exemplary implementation, the fourth protrusion part 74 may be provided on a side of the second anode main body part 52-1 in an opposite direction of the first direction X, an orthographic projection of the fourth protrusion part 74 on the base substrate is at least partially overlapped with an orthographic projection of the second connection electrode 42 and the first power supply line 45 in the circuit unit of the previous column on the base substrate. The fourth protrusion part 74 is configured to adjust flatness of the second anode 52, so that the wires of the third conductive layer below the anode are as symmetrical as possible, which reduces brightness differences and improves the display quality and display effect.

In an exemplary implementation, a second anode 52 of an even-numbered sub-pixel column may not be provided with the fourth protrusion part 74.

In an exemplary implementation, a second anode 52 of an odd-numbered sub-pixel column may include a second anode compensation part 82, an orthographic projection of the anode main body part of the second anode 52 in the odd-numbered sub-pixel column on the base substrate is not overlapped with the orthographic projection of the first connection electrode on the base substrate, and the second anode compensation part 82 is configured so that a parasitic capacitance of the odd-numbered sub-pixel column and a parasitic capacitance of the even-numbered sub-pixel column are substantially the same.

In an exemplary implementation, the second anode compensation part 82 may have a polyline shape extending along the second direction Y, a first end of the second anode compensation part 82 is connected to the second anode connection part 52-2, and a second end of the second anode compensation part 82 extends along a direction away from the second anode main body part 52-1 (an opposite direction of the second direction Y).

In an exemplary implementation, an orthographic projection of the second anode compensation part 82 on the base substrate is at least partially overlapped with the orthographic projection of the first connection electrode 41 on the base substrate. Since the first connection electrode 41 has the potential of the second node N2 in the pixel drive circuit and the second anode compensation part 82 has the potential of the fourth node N4 in the pixel drive circuit, the second anode compensation part 82 and the first connection electrode 41 may form a parasitic capacitor.

In an exemplary implementation, a second anode of an even-numbered sub-pixel column may not include the second anode compensation part, and an orthographic projection of the anode main body part in the second anode of the even-numbered sub-pixel column on the base substrate is at least partially overlapped with the orthographic projection of the first connection electrode on the base substrate.

In an exemplary implementation, the second anode main body part 52-1, the second anode connection part 52-2, the third protrusion part 73, the fourth protrusion part 74, and the second anode compensation part 82 of the odd-numbered sub-pixel column may be interconnected to from an integral structure, and the second anode main body part 52-1, the second anode connection part 52-2, and the third protrusion part 73 of the even-numbered sub-pixel column may be interconnected to from an integral structure.

In an exemplary implementation, a first overlapping area may include an overlapping area of an orthographic projection of the second anode compensation part on the base substrate and the orthographic projection of the first connection electrode on the base substrate, a second overlapping area may include an overlapping area of an orthographic projection of the second anode compensation part on the base substrate and the orthographic projection of the first connection electrode on the base substrate, an orthographic projection of the second anode compensation part of at least one light emitting unit in an odd-numbered sub-pixel column on the base substrate and the orthographic projection of the first connection electrode on the base substrate have the first overlapping area, an orthographic projection of the second anode main body part of at least one light emitting unit in an even-numbered sub-pixel column on the base substrate and the orthographic projection of the first connection electrode on the base substrate have the second overlapping area, and a ratio of the first overlapping area to the second overlapping area may be about from 0.8 to 1.2.

As shown in FIG. 14E, the third anode 53 may include a third anode main body part 53-1 and a third anode connection part 53-2, a shape of the third anode main body part 53-1 may be a hexagon-like shape, a shape of the third anode connection part 53-2 may be a strip shape extending along the second direction Y and is connected to the third anode main body part 53-1, and the third anode connection part 53-2 is configured to be connected to a corresponding third connection electrode 43 through the eleventh via V11.

In an exemplary implementation, a third anode connection part 53-2 of an odd-numbered sub-pixel column may be provided on a side of the third anode main body part 53-1 in an opposite direction of the second direction Y, and a third anode connection part 53-2 of an even-numbered sub-pixel column may be provided on a side of the third anode main body part 53-1 in the second direction Y.

In an exemplary implementation, the third anode 53 may further include a fifth protrusion part 75, wherein a shape of the fifth protrusion part may be a strip shape extending along the second direction Y, a first end of the fifth protrusion part 75 is connected to the third anode main body part 53-1, and a second end of the fifth protrusion part 75 extends along a direction away from the third anode main body part 53-1.

In an exemplary implementation, the fifth protrusion part 75 may be provided on a side of the third anode main body part 53-1 away from the third anode connection part 53-2. For example, a fifth protrusion part 75 of an odd-numbered sub-pixel column may be provided on a side of the third anode main body part 53-1 in the second direction Y, and a fifth protrusion part 75 of an even-numbered sub-pixel column may be provided on a side of the third anode main body part 53-1 in an opposite direction of the second direction Y.

In an exemplary implementation, an orthographic projection of the fifth protrusion part 75 on the base substrate is at least partially overlapped with an orthographic projection of the first scan signal line 21 and the gate block 21-1 on the base substrate, and the fifth protrusion part 75 is configured to shield the second transistor T2, so as to improve the electrical performance of the second transistor T2, and improve the display quality and display effect.

In an exemplary implementation, a third anode 53 of an odd-numbered sub-pixel column may further include a sixth protrusion part 76. A shape of the sixth protrusion part 76 may be a strip shape extending along the first direction X, a first end of the sixth protrusion part 76 is connected to the third anode main body part 53-1, and a second end of the sixth protrusion part 76 extends along a direction away from the third anode main body part 53-1.

In an exemplary implementation, the sixth protrusion part 76 may be provided on a side of the third anode main body part 53-1 in an opposite direction of the first direction X, an orthographic projection of the sixth protrusion part 76 on the base substrate is at least partially overlapped with an orthographic projection of the second connection electrode 42 and the first power supply line 45 in the circuit unit of the previous column on the base substrate. The sixth protrusion part 76 is configured to adjust flatness of the third anode 53 so that the wires of the third conductive layer below the anode are as symmetrical as possible, which reduces brightness differences and improves the display quality and display effect.

In an exemplary implementation, the third anode 53 of the even-numbered sub-pixel column may not be provided with the sixth protrusion part 76.

In an exemplary implementation, a third anode 53 of an odd-numbered sub-pixel column may include a third anode compensation part 83, an orthographic projection of the anode main body part of the third anode 53 of the odd-numbered sub-pixel column on the base substrate is not overlapped with the orthographic projection of the first connection electrode on the base substrate, and the third anode compensation part 83 is configured so that a parasitic capacitance of the odd-numbered sub-pixel column and a parasitic capacitance of the even-numbered sub-pixel column are substantially the same.

In an exemplary implementation, the third anode compensation part 83 may have a polyline shape or a strip shape extending along the second direction Y, a first end of the third anode compensation part 83 is connected to the third anode connection part 53-2, and a second end of the third anode compensation part 83 extends along a direction away from the third anode main body part 53-1 (an opposite direction of the second direction Y).

In an exemplary implementation, an orthographic projection of the third anode compensation part 83 on the base substrate is at least partially overlapped with the orthographic projection of the first connection electrode 41 on the base substrate. Since the first connection electrode 41 has the potential of the second node N2 in the pixel drive circuit and the third anode compensation part 83 has the potential of the fourth node N4 in the pixel drive circuit, the third anode compensation part 83 and the first connection electrode 41 may form a parasitic capacitor.

In an exemplary implementation, a third anode of an even-numbered sub-pixel column may not include the third anode compensation part, and an orthographic projection of the anode main body part in the third anode of the even-numbered sub-pixel column on the base substrate is at least partially overlapped with the orthographic projection of the first connection electrode on the base substrate.

In an exemplary implementation, the third anode main body part 53-1, the third anode connection part 53-2, the fifth protrusion part 75, the sixth protrusion part 76, and the third anode compensation part 83 of the odd-numbered sub-pixel column may be interconnected to form an integral structure, and the third anode main body part 53-1, the third anode connection part 53-2, and the fifth protrusion part 75 of the even-numbered sub-pixel column may be interconnected to form an integral structure.

In an exemplary implementation, a first overlapping area may include an overlapping area of an orthographic projection of the third anode compensation part on the base substrate and the orthographic projection of the first connection electrode on the base substrate, a second overlapping area may include an overlapping area of an orthographic projection of the third anode compensation part on the base substrate and the orthographic projection of the first connection electrode on the base substrate. An orthographic projection of the third anode compensation part of at least one light emitting unit in an odd-numbered sub-pixel column on the base substrate and the orthographic projection of the first connection electrode on the base substrate have the first overlapping area, and an orthographic projection of the third anode main body part of at least one light emitting unit in an even-numbered sub-pixel column on the base substrate and the orthographic projection of the first connection electrode on the base substrate have the second overlapping area. A ratio of the first overlapping area to the second overlapping area may be about from 0.8 to 1.2.

In an exemplary implementation, the protrusion part 70 may include a first protrusion part 71, a second protrusion part 72, a third protrusion part 73, a fourth protrusion part 74, and a fifth protrusion part 75; and the anode compensation part 80 may include a first anode compensation part 81, a second anode compensation part 82, and a third anode compensation part 83.

(8) A pattern of a pixel definition layer is formed. In an exemplary implementation, forming the pattern of the pixel definition layer may include: depositing a pixel definition layer thin film on the base substrate on which the aforementioned patterns are formed, patterning the pixel definition layer through a patterning process to form the pattern of the pixel definition layer provided on an anode conductive layer, as shown in FIG. 15A to FIG. 15D, and FIG. 15B to FIG. 15D are planar schematic diagrams of the pixel definition layer in FIG. 15A.

In an exemplary implementation, the pattern of the pixel definition layer may include multiple pixel openings 60, and the pixel opening exposes an anode 50. In an exemplary implementation, an orthographic projection of the pixel opening on the base substrate is located within a range of an orthographic projection of the anode 50 on the base substrate.

In an exemplary implementation, the pixel opening 60 may include a pixel opening 61 of a first sub-pixel, a pixel opening 62 of a second sub-pixel, and a pixel opening 63 of a third sub-pixel. Among them, the pixel opening 61 of the first sub-pixel to the pixel opening 63 of the third sub-pixel may be hexagonal.

In an exemplary implementation, a ratio between a size of the pixel opening 61 of the first sub-pixel in the first direction X and a size of the pixel opening 61 of the first sub-pixel in the second direction Y is greater than a ratio between a size of the pixel opening 62 of the second sub-pixel in the first direction X and a size of the pixel opening 62 of the second sub-pixel in the second direction Y, and greater than a ratio between a size of the pixel opening 63 of the third sub-pixel in the first direction X and a size of the pixel opening 63 of the third sub-pixel in the second direction Y.

In an exemplary implementation, the ratio between the size of the pixel opening 61 of the first sub-pixel in the first direction X and the size of the pixel opening 61 of the first sub-pixel in the second direction Y may be greater than 1.

In an exemplary implementation, in a same sub-pixel row, the pixel opening 61 of the first sub-pixel, the pixel opening 62 of the second sub-pixel, and the pixel opening 63 of the third sub-pixel are arranged periodically in the first direction X, in the first direction X a distance between the pixel opening 61 of the first sub-pixel and the pixel opening 62 of an adjacent second sub-pixel is at least greater than a distance between the pixel opening 62 of the second sub-pixel and the pixel opening 63 of an adjacent third sub-pixel.

In an exemplary implementation, in a same sub-pixel row and in the first direction X, a distance between the pixel opening 61 of the first sub-pixel and the pixel opening 63 of an adjacent third sub-pixel is greater than the distance between the pixel opening 62 of the second sub-pixel and the pixel opening 63 of the adjacent third sub-pixel.

In an exemplary implementation, in a same sub-pixel row and in the first direction X, the distance between the pixel opening 61 of the first sub-pixel and the pixel opening 62 of the adjacent second sub-pixel is greater than or equal to the distance between the pixel opening 61 of the first sub-pixel and the pixel opening 63 of the adjacent third sub-pixel.

In an exemplary implementation, as shown in FIG. 15K, it is an enlarged schematic diagram of a structure of the pixel opening 61 of the first sub-pixel in FIG. 15B. The pixel opening 61 of the first sub-pixel may be hexagonal, and the hexagonal pixel opening 61 of the first sub-pixel may include a first edge D11 and a second edge D12 that are oppositely provided in the first direction X, at least one of the first edge D11 and the second edge D12 has a size h11 of 4 microns to 9 microns in the second direction Y, and the first direction X intersects with the second direction Y.

In an exemplary implementation, in a same sub-pixel row and in the first direction X, the first edge D11 of the pixel opening 61 of the first sub-pixel is close to the pixel opening 63 of an adjacent third sub-pixel, the second edge D12 of the pixel opening 61 of the first sub-pixel is close to the pixel opening 62 of an adjacent second sub-pixel, and a size of the second edge D12 in the second direction Y is greater than or equal to a size of the first edge D11 in the second direction Y.

In an exemplary implementation, as shown in FIG. 15K, a rhombus in which the pixel opening 61 of the first sub-pixel is located includes two included angles provided oppositely in the first direction X, in the first direction X the two included angles are located on two sides of the first edge D11 and the second edge D12, and a distance between at least one of the first edge D11 and the second edge D12 and a vertex of an included angle adjacent thereto is 3 microns to 6 microns in the first direction X. In an exemplary implementation, a distance h12 between the first edge D11 and a vertex of a first included angle f11 is 3 microns to 6 microns in the first direction X, and a distance h12 between the second edge D12 and a vertex of a second included angle f12 is 3 microns to 6 microns in the first direction X.

In an exemplary implementation, the two included angles may include the first included angle f11 and the second included angle f12, in the first direction X, the first included angle f11 is located on a side of the first edge D11 away from the second edge D12, the second included angle f12 is located on a side of the second edge D12 away from the first edge D11, and a distance between the vertex of the second included angle f12 and the second edge D12 is greater than or equal to a distance between the vertex of the first included angle f11 and the first edge D11.

In an exemplary implementation, a size h11 of at least one of the first edge D11 and the second edge D12 may be 7.8716 microns in the second direction Y, the distance h12 between the first edge D11 and the vertex of the first included angle f11 may be 5.2314 microns in the first direction X, and the distance h12 between the second edge D12 and the vertex of the second included angle f12 may be 5.2314 microns in the first direction X; or, a size h11 of at least one of the first edge D11 and the second edge D12 may be 5.7919 microns in the second direction Y, the distance h12 between the first edge D11 and the vertex of the first included angle f11 may be 3.6432 microns in the first direction X, and the distance h12 between the second edge D12 and the vertex of the second included angle f12 may be 3.6432 microns in the first direction X.

In an implementation of the present disclosure, sizes of the pixel opening 61 of the first sub-pixel and the first anode 51 of the first sub-pixel in the first direction X are contracted, so that an orthographic projection of the anode compensation part 82 in the second anode 52 in the second sub-pixel on the base substrate and an orthographic projection of the anode compensation part 83 in the third anode 53 of the third sub-pixel on the base substrate can be at least partially overlapped with an orthographic projection of the first connection electrode 41 on the base substrate, wherein the second anode 52 and the third anode 53 are located on two sides of the first anode 51, and differences of parasitic capacitances generated by the first sub-pixel column and the second sub-pixel column and the corresponding unit columns can be reduced as much as possible.

In the related art, when a size of the pixel opening 61 of the first sub-pixel corresponding to the first anode 51 in the first direction X is not contracted, the size h11 of the first edge D11 and the second edge D12 in the second direction Y is usually 0.4 microns. During production, due to a small size, the first edges D11 and the second edges D12 of the pixel openings 61 of some first sub-pixels often form arc shapes due to process fluctuations, resulting in inconsistent shapes of the pixel openings 61 of the first sub-pixels. In an embodiment of the present disclosure, the size h11 of the first edge D11 and the second edge D12 in the second direction Y is slightly increased from 0.4 microns to 4-9 microns, which overcomes the defect of the inconsistent shapes of the pixel openings 61 of the first sub-pixels due to the process fluctuations as a result of the small size. On another aspect, compared with a case that the size of the pixel opening 61 of the first sub-pixel is not contracted in the first direction in the related art, the pixel opening 61 of the first sub-pixel in an embodiment of the present disclosure is contracted by 3 microns to 6 microns unilaterally in the first direction X, so that the first anode 51 is contracted by 3 microns to 6 microns unilaterally in the first direction X, thereby increasing the compensation spaces of the compensation part 82 of the second anode 52 and the compensation part 83 of the third anode 53, i.e., when a limit of the anode compensation is reached, by compressing the pixel opening 61 of the first sub-pixel, the compensation spaces of the compensation part 82 of the second anode 52 and the compensation part 83 of the third anode 53 on the left and right sides of the first sub-pixel in the same sub-pixel row can be improved, so that an orthographic projection of the anode compensation part 82 of the second anode 52 on the base substrate and an orthographic projection of the anode compensation part 83 of the third anode 53 on the base substrate are at least partially overlapped with the orthographic projection of the first connection electrode 41 on the base substrate, a parasitic capacitance of the first sub-pixel column is increased, and a difference between the parasitic capacitance of the first sub-pixel column and a parasitic capacitance of the second sub-pixel column is reduced, as a result it can make the parasitic capacitance of the first sub-pixel column and the parasitic capacitance of the second sub-pixel column substantially the same, which effectively eliminates vertical display defects and improves display quality and display effect. In the related art, in the case that the size of the pixel opening 61 of the first sub-pixel in the first direction X is not contracted and compensation of the anode compensation part reaches the compensation limit, since the size of the first anode 51 in the first direction X is relatively great, there is still the difference of about 36.17% between the parasitic capacitances generated by the second anode 52 of the first sub-pixel column and the second anode 52 of the second sub-pixel column and corresponding circuit units thereof. But in an embodiment of the present disclosure, the size of the pixel opening 61 of the first sub-pixel in the first direction X is contracted, the size of the corresponding first anode 51 in the first direction X is also contracted, compensation space of the second anode 52 is increased, the difference in parasitic capacitances generated by the second anode 52 of the first sub-pixel column and the second anode 52 of the second sub-pixel column and the corresponding circuit units thereof is reduced to approximately 10.57%, and the difference is reduced by approximately 25.6%, which improves the display effect to a great extent.

In an implementation of the present disclosure, as shown in FIG. 15K and FIG. 15L, in order to keep areas of the first anode 51 main body part and the pixel opening 61 of the first sub-pixel unchanged, sizes of the first anode 51 main body part and the pixel opening 61 of the first sub-pixel in the second direction Y can be increased when sizes are contracted in the first direction X. In FIG. 15K, a contour 51-01 is a contour of the first anode 51 main body part without contraction, and a contour 61-01 is a contour of the pixel opening 61 of the first sub-pixel without contraction. An embodiment of the present disclosure sizes are increased appropriately in the second direction Y (i.e., sizes are expanded in the second direction), other anode compensation parts would not be sheltered, and it is ensured that when sizes of the first anode 51 main body part and the pixel opening 61 of the first sub-pixel are contracted in the first direction X, areas of the first anode 51 main body part and the pixel opening 61 of the first sub-pixel are substantially the same as areas when no contraction are performed on these sizes.

In an implementation of the present disclosure, the first anode 51 main body part and the pixel opening 61 of the first sub-pixel can be contracted unilaterally in the first direction X. For example, after a first edge D11 is contracted, a distance between the first edge D11 and a vertex of a first included angle f11 is h12, and a distance between a second edge D12 and a vertex of the second included angle f2 will not be contracted. Or, only the second edge D12 is contracted, and the first edge D11 is not contracted. Whether sizes of the first anode 51 main body part and the pixel opening 61 of the first sub-pixel in the first direction X are contracted unilaterally or bilaterally depends on the influence of the first anode 51 on the second anode 52 or the influence of the first anode 51 on the third anode 53.

Due to characteristics of Delta pixel arrangement, a first anode of an odd-numbered sub-pixel column and a first anode of an even-numbered sub-pixel column are not on a same horizontal line, and a pixel drive circuit of an odd-numbered unit column and a pixel drive circuit of an even-numbered unit column are on a same horizontal line, so that a corresponding region of the first anode of the odd-numbered sub-pixel column and the pixel drive circuit is different from a corresponding region of the first anode of the even-numbered sub-pixel column and the pixel drive circuit, an orthographic projection of the first anode of the odd-numbered sub-pixel column on the base substrate is at least partially overlapped with an orthographic projection of the first transistor T1 and the seventh transistor T7 of the pixel drive circuit on the base substrate, and an orthographic projection of the first anode of the even-numbered sub-pixel column on the base substrate is at least partially overlapped with an orthographic projection of the second transistor T2, the third transistor T3, and the storage capacitor of the pixel drive circuit on the base substrate. In addition, since the second anode of the odd-numbered sub-pixel column and the second anode of the even-numbered sub-pixel column are not on a same horizontal line, a corresponding region of the second anode of the odd-numbered sub-pixel column and the pixel drive circuit is different from a corresponding region of the second anode of the even-numbered sub-pixel column and the pixel drive circuit. Since the third anode of the odd-numbered sub-pixel column and the third anode of the even-numbered sub-pixel column are not on a same horizontal line, a corresponding region of the third anode of the odd-numbered sub-pixel column and the pixel drive circuit is different from a corresponding region of the third anode of the even-numbered sub-pixel column and the pixel drive circuit.

In an exemplary implementation, the anode main body part of the even-numbered sub-pixel column is located in a region where the storage capacitor is located, an orthographic projection of the anode main body part of the even-numbered sub-pixel column on the base substrate is at least partially overlapped with the orthographic projection of the first connection electrode 41 on the base substrate, while a distance between the anode main body part of the odd-numbered sub-pixel column and the storage capacitor is relatively great, and an orthographic projection of the anode main body part of the odd-numbered sub-pixel column on the base substrate is not overlapped with the orthographic projection of the first connection electrode 41 on the base substrate, so that for a parasitic capacitor formed by the second node N2 and the fourth node N4, a parasitic capacitance of the even-numbered sub-pixel column is greater than a parasitic capacitance of the odd-numbered sub-pixel column. It is found in the research that in a light emitting initial stage of a pixel, the potential of the fourth node N4 will increase with the increase of brightness, which thereby will bring the potential of the second node N2 to increase. When the parasitic capacitance of the odd-numbered sub-pixel column is different from the parasitic capacitance of the even-numbered sub-pixel column, the increasing degree of the potential of the second node N2 of the odd-numbered sub-pixel column is different from the increasing degree of the potential of the second node N2 of the even-numbered sub-pixel column, so that the brightness of the light emitting unit of the odd-numbered sub-pixel column is different from the brightness of the light emitting unit of the even-numbered sub-pixel column, resulting in a display defect with vertical stripes.

The display substrate provided by an exemplary embodiment of the present disclosure, in one aspect, in the present disclosure the anode of the first sub-pixel column includes an anode compensation part extending along a direction of the first connection electrode, and an orthographic projection of the anode compensation part on the base substrate is at least partially overlapped with the orthographic projection of the first connection electrode on the base substrate, thereby the parasitic capacitance of the first sub-pixel column is increased, and a difference between the parasitic capacitance of the first pixel column and the parasitic capacitance of the second pixel column is reduced. In another aspect, in the present disclosure by contracting the sizes of the first anode and the pixel opening of the first light emitting unit in the first direction, the space of the anode compensation part of the second anode or the third anode is increased, and an orthographic projection of the first connection electrode on the base substrate is at least partially overlapped with an orthographic projection of the anode compensation part on the base substrate, a difference between a parasitic capacitance of the second anode in the first sub-pixel column and the corresponding circuit unit and a parasitic capacitance of the second anode in the second sub-pixel column and the corresponding circuit unit is further reduced. In the present disclosure by providing the anode compensation part and contracting the sizes of the first anode and the pixel opening of the first light emitting unit in the first direction, the difference between the parasitic capacitance of the first sub-pixel column and the parasitic capacitance of the second sub-pixel column is effectively reduced, as a result the parasitic capacitance of the first sub-pixel column and the parasitic capacitance of the second sub-pixel column are substantially the same, which effectively eliminates vertical display defects and improves display quality and display effect. The manufacturing process in the present disclosure may be compatible well with an existing manufacturing process, is simple in process implementation, is easy to implement, and has a high production efficiency, a low production cost, and a high yield.

In an exemplary implementation, a subsequent manufacturing process may include: forming an organic emitting layer using an evaporation or inkjet printing process, wherein the organic emitting layer is connected to an anode through a pixel opening, and forming a cathode on the organic emitting layer, wherein the cathode is connected to the organic emitting layer; forming an encapsulation structure layer, wherein the encapsulation structure layer may include a first encapsulation layer, a second encapsulation layer, and a third encapsulation layer that are stacked, the first encapsulation layer and the third encapsulation layer may be made of an inorganic material, the second encapsulation layer may be made of an organic material, and the second encapsulation layer is provided between the first encapsulation layer and the third encapsulation layer, so that it may be ensured that external water vapor cannot enter a light emitting structure layer.

(9) A pattern of a light emitting layer is formed. In an exemplary implementation, forming the pattern of the light emitting layer may include: depositing a light emitting layer thin film on the base substrate on which the aforementioned patterns are formed, patterning the light emitting layer through a patterning process to form the pattern of the light emitting layer located within the pixel opening and provided on the anode conductive layer, as shown in FIG. 15E to FIG. 15H, and FIG. 15F is a planar schematic diagram of the light emitting layer in FIG. 15E.

As shown in FIG. 15F to FIG. 15H, an orthographic projection of the light emitting layer on the base substrate is at least partially overlapped with an orthographic projection of the corresponding pixel opening on the base substrate.

In an exemplary implementation, as shown in FIG. 15F, at least some of the light emitting layers of adjacent sub-pixels are spaced, and spacings between the light emitting layers of different sub-pixels are different; in FIG. 15F, a shape and size of the light emitting layer is consistent with a shape and size of the corresponding sub-pixel opening 60.

In an exemplary implementation, as shown in FIG. 15G, at least some of the light emitting layers of adjacent sub-pixels are overlapped, and the overlapping areas are different, so that a Shadow effect can be avoided; during a process of deposition of a light emitting layer material, the mask opening will have Shadow effect on the deposition of the light emitting layer material. In order to avoid the Shadow effect, the light emitting layer material can be expanded, and there is an overlapping between the light emitting layers of adjacent sub-pixels. For example, an overlapping area of the second light emitting layer 92 and the first light emitting layer 91 is different from an overlapping area of the second light emitting layer 92 and the third light emitting layer 93.

In an exemplary implementation, as shown in FIG. 15H, some of the light emitting layers of adjacent sub-pixels are overlapped, and some of the light emitting layers of adjacent sub-pixels are spaced. For example, the second light emitting layer 92 may be overlapped with an adjacent light emitting layer, and the first light emitting layer 91 is not overlapped with an adjacent third light emitting layer 93.

The aforementioned structure shown in the present disclosure and the manufacturing process thereof are merely exemplary description. In an exemplary implementation, corresponding structures may be changed and patterning processes may be added or reduced according to actual needs, which is not limited here in the present disclosure.

FIG. 16A is a schematic diagram of a structure of another display substrate according to an exemplary embodiment of the present disclosure, FIG. 16B is a planar schematic diagram of the third conductive layer in FIG. 16A, and FIG. 16C is a planar schematic diagram of the anode conductive layer in FIG. 16A. In an exemplary implementation, a structure of the display substrate of this embodiment is substantially the same as a structure of the display substrate shown in FIG. 7, except that the first connection electrode part in the drive circuit layer is provided with an electrode compensation part.

As shown in FIG. 16A, FIG. 16B and FIG. 16C, a structure of the drive circuit layer of this embodiment is substantially the same as a structure of the drive circuit layer of the foregoing embodiment, except that the first connection electrode 41 in at least one circuit unit may include an electrode main body part 41-1 and an electrode compensation part 41-2, the electrode compensation part 41-2 is configured to compensate the parasitic capacitance between the second node N2 and the fourth node N4 in the pixel drive circuit to eliminate a difference between the parasitic capacitance of the pixel drive circuit in the odd-numbered unit column and the parasitic capacitance of the pixel drive circuit in the even-numbered unit column.

In an exemplary implementation, a shape of the first connection electrode 41 of at least one circuit unit in the first unit column may be different from a shape of the first connection electrode 41 of at least one circuit unit in the second unit column.

In an exemplary implementation, in the multiple first unit columns, a shape of the first connection electrode 41 of the circuit unit in at least one first unit column may be different from a shape of the first connection electrode 41 of the circuit unit in at least another first unit column.

In an exemplary implementation, in at least one unit column, first connection electrodes 41 of at least two circuit units may have a same shape.

In an exemplary implementation, in at least one unit row, the multiple circuit units may at least include a first circuit unit, a second circuit unit, and a third circuit unit. The pixel drive circuit of the first circuit unit is connected to a red light emitting unit emitting red light, the pixel drive circuit of the second circuit unit is connected to a blue light emitting unit emitting blue light, and the pixel drive circuit of the third circuit unit is connected to a green light emitting unit emitting green light. Shapes of the first connection electrode 41 in the first circuit unit, the first connection electrode 41 in the second circuit unit, and the first connection electrode 41 in the third circuit unit may be the same or different.

In an exemplary implementation, in at least one circuit unit, the electrode main body part 41-1 may include a first end connected to the first plate of the storage capacitor and a second end connected to the first electrode of the compensation transistor, and the electrode compensation part 41-2 may be provided on a side of the first end away from the second end, i.e., the electrode compensation part 41-2 may be provided on a side of the electrode main body part 41-1 in the second direction Y.

In an exemplary implementation, a shape of the electrode main body part 41-1 of at least one circuit unit in the first unit column may be the same as a shape of the electrode main body part 41-1 of at least one circuit unit in the second unit column, and a shape of the electrode compensation part 41-1 of at least one circuit unit in the first unit column may be different from a shape of the electrode compensation part 41-2 of at least one circuit unit in the second unit column.

In an exemplary implementation, the electrode main body part 41-1 in the first circuit unit, the electrode main body part 41-1 in the second circuit unit, and the electrode main body part 41-1 in the third circuit unit may have a same shape, and the electrode compensation part 41-2 in the first circuit unit, the electrode compensation part 41-2 in the second circuit unit, and the electrode compensation part 41-2 in the third circuit unit may have different shapes.

In an exemplary implementation, the first connection electrode 41 of the first circuit unit has a first length L1, the first connection electrode 41 of the second circuit unit has a second length L2, and the first connection electrode 41 of the third circuit unit has a third length L3. The first length L1, the second length L2, and the third length L3 are different, and the first length L1, the second length L2, and the third length L3 are sizes of the first connection electrodes 41 in the second direction Y.

In an exemplary implementation, the second length L2 may be greater than the first length L1, and the second length L2 may be greater than the third length L3.

In an exemplary implementation, the third length L3 may be greater than the first length L1.

In an exemplary implementation, the first connection electrode 41 of the circuit unit in the first unit column may include an electrode main body part and an electrode compensation part, while the first connection electrode 41 of the circuit unit in the second unit column may include only the electrode main body part, and the first connection electrodes 41 having the electrode compensation part 41-2 may be provided in the circuit units of the interleaved unit columns.

In an exemplary implementation, the electrode compensation part 41-2 may have a strip shape extending along the second direction Y, the first end of the electrode compensation part 41-2 is connected to the electrode main body part 41-1, and the second end of the electrode compensation part 41-2 may extend along a direction away from the electrode main body part 41-1 in the second direction Y. Since the first connection electrode 41 has the potential of the second node N2 in the pixel drive circuit, the electrode compensation part 41-2 has the potential of the second node N2 in the pixel drive circuit, and the electrode compensation part 41-2 is configured to increase an overlapping area of the second node N2 in the first sub-pixel column and the anode (the fourth node N4) to be formed subsequently, thereby increasing a parasitic capacitance between the second node N2 and the fourth node N4, such that a parasitic capacitance of the odd-numbered column is substantially the same as a parasitic capacitance of the even-numbered column.

In an exemplary implementation, since the electrode compensation part 41-2 is configured to adjust an overlapping area of the first connection electrode and the anode, and the positions and shapes of the anodes located in different sub-pixel columns may be different, the electrode compensation part 41-2 may be provided in some first unit columns, while the electrode compensation part 41-2 may not be provided in some first unit columns, the positions and shapes of the electrode compensation parts 41-2 may be the same in some circuit units, and the positions and shapes of the electrode compensation parts 41-2 may be different in other circuit units, and the present disclosure is not limited herein.

In an exemplary implementation, an orthographic projection of the first anode compensation part 81 on the base substrate is at least partially overlapped with an orthographic projection of the electrode main body part 41-1 and the electrode compensation part 41-2 in the first connection electrode 41 on the base substrate, or the orthographic projection of the first anode compensation part 81 on the base substrate is at least partially overlapped with an orthographic projection of the electrode compensation part 41-2 in the first connection electrode 41 on the base substrate. Since the first connection electrode 41 has the potential of the second node N2 in the pixel drive circuit and the first anode compensation part 81 has the potential of the fourth node N4 in the pixel drive circuit, the first anode compensation part 81 and the first connection electrode 41 may form a parasitic capacitor.

In an exemplary implementation, an orthographic projection of the second anode compensation part 82 on the base substrate is at least partially overlapped with an orthographic projection of the electrode main body part 41-1 and the electrode compensation part 41-2 in the first connection electrode 41 on the base substrate, or the orthographic projection of the second anode compensation part 82 on the base substrate is at least partially overlapped with an orthographic projection of the electrode compensation part 41-2 in the first connection electrode 41 on the base substrate. Since the first connection electrode 41 has the potential of the second node N2 in the pixel drive circuit and the second anode compensation part 82 has the potential of the fourth node N4 in the pixel drive circuit, the second anode compensation part 82 and the first connection electrode 41 may form a parasitic capacitor.

In an exemplary implementation, an orthographic projection of the third anode compensation part 83 on the base substrate is at least partially overlapped with an orthographic projection of the electrode main body part 41-1 and the electrode compensation part 41-2 in the first connection electrode 41 on the base substrate, or the orthographic projection of the third anode compensation part 83 on the base substrate is at least partially overlapped with an orthographic projection of the electrode compensation part 41-2 in the first connection electrode 41 on the base substrate. Since the first connection electrode 41 has the potential of the second node N2 in the pixel drive circuit and the third anode compensation part 83 has the potential of the fourth node N4 in the pixel drive circuit, the third anode compensation part 83 and the first connection electrode 41 may form a parasitic capacitor. In an exemplary implementation, an orthographic projection of the anode main body part of at least one light emitting unit in the first sub-pixel column on the base substrate is not overlapped with the orthographic projection of the first connection electrode 41 on the base substrate, and an orthographic projection of the anode main body part of at least one light emitting unit in the second sub-pixel column on the base substrate is at least partially overlapped with the orthographic projection of the first connection electrode 41 on the base substrate.

In an exemplary implementation, as shown in FIG. 16C, the anode 50 of at least one light emitting unit in the first sub-pixel column may include an anode main body part 50-1 and an anode compensation part 50-2, structures of the anode main body part 50-1 and the anode compensation part 50-2 are substantially the same as structures of the foregoing embodiment, and an orthographic projection of the anode compensation part 50-2 on the base substrate is at least partially overlapped with the orthographic projection of the first connection electrode 41 on the base substrate.

In the display substrate provided by an exemplary embodiment of the present disclosure a difference between the parasitic capacitance of the first sub-pixel column and the parasitic capacitance of the second sub-pixel column is effectively reduced using the first connection electrode including the electrode compensation part. In one aspect, in the present disclosure the anode of the first sub-pixel column includes an anode compensation part extending along a direction of the first connection electrode, and the orthographic projection of the anode compensation part on the base substrate is at least partially overlapped with the orthographic projection of the first connection electrode on the base substrate, thereby the parasitic capacitance of the first sub-pixel column is increased, and the difference between the parasitic capacitance of the first sub-pixel column and the parasitic capacitance of the second sub-pixel column is reduced. In another aspect, in the present disclosure the first connection electrode of the first sub-pixel column includes an electrode compensation part extending along a direction of the anode, and the orthographic projection of the electrode compensation part on the base substrate is at least partially overlapped with the orthographic projection of the anode compensation part on the base substrate, the parasitic capacitance of the first sub-pixel column is further increased, and the difference between the parasitic capacitance of the first sub-pixel column and the parasitic capacitance of the second sub-pixel column is further reduced. In yet another aspect, in an embodiment of the present disclosure by contracting the size of the first anode in the first direction, increasing the space of the anode compensation part of the second anode or the third anode, and the orthographic projection of the first connection electrode on the base substrate is at least partially overlapped with the orthographic projection of the anode compensation part on the base substrate, the difference between the parasitic capacitance of the second anode in the first sub-pixel column and the corresponding circuit unit and the parasitic capacitance of the second anode in the second sub-pixel column and the corresponding circuit unit is further reduced, and the defect of inconsistent shapes of the openings and the light emitting layers caused by process fluctuations in the pixel openings and the light emitting layers of the first light emitting units (i.e., the pixel openings 61 and the light emitting layers 91 of the first sub-pixels P1) can be overcome. In the present disclosure by providing the electrode compensation part and the anode compensation part and contracting the sizes of the first anode and the pixel opening of the first light emitting unit in the first direction, so that the compensation space of the second anode or the third anode is increased, the difference between the parasitic capacitance of the first sub-pixel column and the parasitic capacitance of the second sub-pixel column is effectively reduced, as a result it can make the parasitic capacitance of the first sub-pixel column and the parasitic capacitance of the second sub-pixel column substantially the same, which effectively eliminates vertical display defects and improves display quality and display effect, and the defect of inconsistent shapes of the first anodes caused by process fluctuations in first anodes can be overcome. The manufacturing process in the present disclosure may be compatible well with an existing manufacturing process, is simple in process implementation, is easy to implement, and has a high production efficiency, a low production cost, and a high yield.

In the display substrate provided by an exemplary embodiment of the present disclosure, in one aspect, the parasitic capacitance of the first sub-pixel column is increased by providing the anode compensation part on the anode of the first sub-pixel column, in another aspect, the parasitic capacitance of the first sub-pixel column is increased by providing the electrode compensation part on the first connection electrode of the first sub-pixel column, in yet another aspect, the compensation space of the second anode or the third anode is increased by reducing sizes of the first anode and the pixel opening and the light emitting layer of the first light emitting unit in the first direction, so that the difference between the parasitic capacitance of the first sub-pixel column and the parasitic capacitance of the second sub-pixel column is reduced, the parasitic capacitance of the first sub-pixel column and the parasitic capacitance of the second sub-pixel column are substantially the same, which effectively eliminates vertical display defects under full gray scale and improves display quality and display effect to a maximum extent, and the defect of inconsistent shapes of the first anodes caused by process fluctuations in first anode can be overcome.

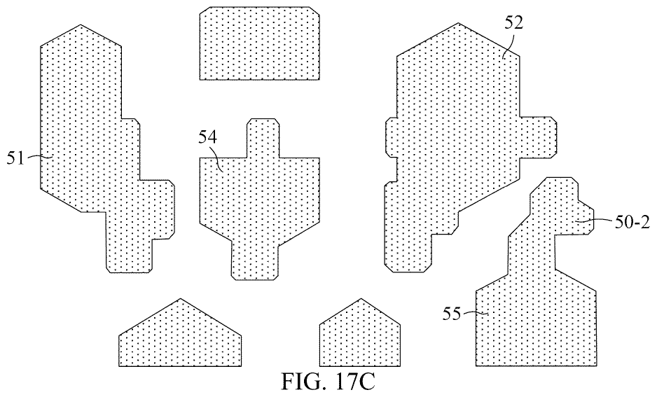

FIG. 17A is a schematic diagram of a structure of yet another display substrate according to an exemplary embodiment of the present disclosure, FIG. 17B is a planar schematic diagram of the third conductive layer in FIG. 17A, and FIG. 17C is a planar schematic diagram of the anode conductive layer in FIG. 17A, illustrating a GGRB pixel arrangement. As shown in FIG. 17A, FIG. 17B, and FIG. 17C, the drive circuit layer may at least include a first connection electrode 41 and a third connection electrode 43, and the light emitting structure layer may include multiple anodes 50.

In an exemplary implementation, the first connection electrode 41 may have a strip shape extending along the second direction Y, a first end of the first connection electrode 41 is connected to a first plate of the storage capacitor through a via, a second end of the first connection electrode 41 is connected to a first region of the second active layer through a via, and the first connection electrode 41 may serve as the second node N2 in the pixel drive circuit.

In an exemplary implementation, the third connection electrode 43 may have a polygonal shape, the third connection electrode 43 is connected to the second electrode of the sixth transistor and the second electrode of the seventh transistor through a via, and the third connection electrode 43 may serve as the fourth node N4 in the pixel drive circuit.

In an exemplary implementation, the multiple anodes 50 may at least include a first anode 51 of a red light emitting unit, a second anode 52 of a blue light emitting unit, a fourth anode 54 of a first green light emitting unit, and a fifth anode 55 of a second green light emitting unit. A red light emitting unit R that emits red light may be formed in a region where the first anode 51 is located, a blue light emitting unit B that emits blue light may be formed in a region where the second anode 52 is located, a first green light emitting unit G1 that emits green light may form in a region where the fourth anode 54 is located can form, and a second green light emitting unit G2 that emits green light may be formed in a region where the fifth anode 55 is located can form. The red light emitting unit R and the blue light emitting unit B may be sequentially provided in the first direction X. The first green light emitting unit G1 and the second green light emitting unit G2 may be sequentially provided in the second direction Y, and in the first direction X, the first green light emitting unit G1 and the second green light emitting unit G2 may be provided between the red light emitting unit R and the blue light emitting unit B to form a GGRB arrangement.

In an exemplary embodiment, the positional relationship between the four anodes and the circuit unit may be different, a main body part of the fourth anode 54 is located on a side of the corresponding connection circuit unit in the second direction Y, and a main body part of the fifth anode 55 is located in a circuit unit of a next row of the corresponding connection circuit unit. Since the circuit units corresponding to the fourth anode 54 and the fifth anode 55 are not on a same horizontal line, for a parasitic capacitance formed by the anode and the first connection electrode, the parasitic capacitance of the first green light emitting unit G1 is greatly different from the parasitic capacitance of the second green light emitting unit G2.

In an exemplary embodiment, the anode may include an anode main body part and an anode connection part, the anode connection part is configured to be connected to the third connection electrode 43 in a corresponding circuit unit through a via, an orthographic projection of the anode main body part of the fourth anode 54 of the first green light emitting unit G1 on the base substrate is at least partially overlapped with the orthographic projection of the first connection electrode 41 on the base substrate, and the orthographic projection of the anode main body part of the fifth anode 55 of the second green light emitting unit G2 on the base substrate is not overlapped with the orthographic projection of the first connection electrode 41 on the base substrate.

In an exemplary embodiment, the fifth anode 55 of the second green light emitting unit G2 may further include an anode compensation part 50-2, a first end of the anode compensation part 50-2 is connected to the anode connection part of the fifth anode 55, a second end of the anode compensation part 50-2 extends along a direction away from the anode main body part, an orthographic projection of the anode compensation part 50-2 on the base substrate is at least partially overlapped with the orthographic projection of the first connection electrode 41 on the base substrate, an orthographic projection of the fourth anode 54 on the base substrate has a first overlapping area with the orthographic projection of the first connection electrode 41 on the base substrate, an orthographic projection of the anode compensation part 50-2 of the fifth anode 55 on the base substrate has a second overlapping area with the orthographic projection of the first connection electrode 41 on the base substrate, and a ratio of the first overlapping area to the second overlapping area may be about from 0.8 to 1.2.

In another exemplary embodiment, the fifth anode of the second green light emitting unit G2 may further include an anode compensation part, the first connection electrode in the circuit unit connected to the fifth anode may further include an electrode compensation part, the orthographic projection of the electrode compensation part on the base substrate is at least partially overlapped with the orthographic projection of the anode compensation part on the base substrate, an orthographic projection of the fourth anode on the base substrate has a first overlapping area with the orthographic projection of the first connection electrode on the base substrate, an orthographic projection of the anode compensation part of the fifth anode on the base substrate has a second overlapping area with the orthographic projection of the electrode compensation part of the first connection electrode on the base substrate, and a ratio of the first overlapping area to the second overlapping area may be about from 0.9 to 1.1.

The display substrate provided by an exemplary embodiment of the present disclosure can effectively reduce a difference between the parasitic capacitance of the first green light emitting unit and the parasitic capacitance of the second green light emitting unit, can enable the parasitic capacitance of the first green light emitting unit to be substantially the same as the parasitic capacitance of the second green light emitting unit, and can not only ensure the consistency of green brightness, but also eliminate the defect with vertical strips under the full gray scale, thereby improving the display quality and display effect.

The present disclosure also provides a display apparatus which includes the aforementioned display substrate. The display apparatus may be any product or component with a display function, such as a mobile phone, a tablet computer, a television, a display, a laptop computer, a digital photo frame, and a navigator, and an embodiment of the present disclosure is not limited thereto.

Embodiments of the present disclosure provide a display substrate and a display apparatus, in the display substrate, at least one first sub-pixel is adjacent to both the second sub-pixel and the third sub-pixel, and a closest distance of a pixel opening of at least one first sub-pixel to a pixel opening of an adjacent second sub-pixel is different from a closest distance of a pixel opening of the at least one first sub-pixel to a pixel opening of an adjacent third sub-pixel, so that the anode compensation space of at least one of the second sub-pixel and the third sub-pixel may be adjusted, and the parasitic capacitances of the sub-pixels may be adjusted to make the parasitic capacitances of multiple sub-pixels as consistent as possible.

Although the implementations of the present disclosure are disclosed above, the contents are only implementations used for ease of understanding of the present disclosure, but not intended to limit the present disclosure. Those skilled in the art may make any modification and change in the forms and details of the implementations without departing from the essence and scope of the present disclosure. However, the scope of protection of the present disclosure should still be subject to the scope defined by the attached claims.

1. A display substrate, comprising a plurality of sub-pixels and a pixel definition layer, wherein a plurality of pixel openings are formed in the pixel definition layer, and each sub-pixel comprises at least one pixel opening;
the plurality of sub-pixels comprise a first sub-pixel, a second sub-pixel, and a third sub-pixel, wherein at least one first sub-pixel is adjacent to a second sub-pixel and a third sub-pixel, and a closest distance between a pixel opening of the at least one first sub-pixel and a pixel opening of an adjacent second sub-pixel is different from a closest distance between the pixel opening of the at least one first sub-pixel and a pixel opening of an adjacent third sub-pixel.

2. The display substrate according to claim 1, wherein the at least one first sub-pixel is at least adjacent to two second sub-pixels, and the at least one first sub-pixel is at least adjacent to two third sub-pixels, and a closest distance between the pixel opening of the at least one first sub-pixel and a pixel opening of another adjacent second sub-pixel is the same as a closest distance between the pixel opening of the at least one first sub-pixel and a pixel opening of another adjacent third sub-pixel.

3. The display substrate according to claim 1, wherein one first sub-pixel, one second sub-pixel, and one third sub-pixel are sequentially arranged in a first direction, and a closest distance between a pixel opening of a first sub-pixel and a pixel opening of a second sub-pixel is different from a closest distance between the pixel opening of the second sub-pixel and a pixel opening of a third sub-pixel, and the first direction is one of a row direction or a column direction.

4. The display substrate according to claim 1, wherein the at least one first sub-pixel is at least adjacent to two second sub-pixels, and closest distances between the pixel opening of the at least one first sub-pixel and pixel openings of the adjacent two second sub-pixels are different;
or
the at least one first sub-pixel is at least adjacent to two third sub-pixels, and closest distances between the pixel opening of the at least one first sub-pixel and pixel openings of the adjacent two third sub-pixels are different.

5. (canceled)

6. The display substrate according to claim 1, wherein a closest distance from a pixel opening of a sub-pixel located in a same row as a pixel opening of the at least one first sub-pixel and adjacent to the at least one first sub-pixel to the pixel opening of the at least one first sub-pixel is different from a closest distance from a pixel opening of a sub-pixel located in a different row from the pixel opening of the at least one first sub-pixel and adjacent to the at least one first sub-pixel to the pixel opening of the at least one first sub-pixel.

7. (canceled)

8. The display substrate according to claim 1, wherein opposite sides of pixel openings of at least a portion of sub-pixels and pixel openings of a portion of adjacent sub-pixels are parallel sides, and parts of pixel openings of the at least a portion of sub-pixels opposite to pixel openings of some other adjacent sub-pixels comprise an angle, a rounded angle, or a side with a side length less than 1/10 of a perimeter of a pixel opening of the sub-pixel.

9. The display substrate according to claim 1, wherein the plurality of sub-pixels comprise light emitting layers corresponding to pixel openings, the first sub-pixel comprises a first light emitting layer, the second sub-pixel comprises a second light emitting layer, and the third sub-pixel comprises a third light emitting layer;
a closest distance from at least one first light emitting layer to an adjacent second light emitting layer is different from a closest distance from the at least one first light emitting layer to an adjacent third light emitting layer.

10. The display substrate according to claim 9, wherein light emitting layers of at least a portion of adjacent sub-pixels are spaced, and spacings between light emitting layers of different sub-pixels are different; or light emitting layers of at least a portion of adjacent sub-pixels are overlapped, and overlapping areas are different; or
light emitting layers of a portion of adjacent sub-pixels are overlapped, and light emitting layers of another portion of adjacent sub-pixels are spaced.

11. (canceled)

12. The display substrate according to claim 9, wherein the at least one first light emitting layer is at least adjacent to two second light emitting layers, and the at least one first light emitting layer is at least adjacent to two third light emitting layers, and a closest distance from the at least one first light emitting layer to another adjacent second light emitting layer is the same as a closest distance from the at least one first light emitting layer to another adjacent third light emitting layer.

13. The display substrate according to claim 9, wherein one first light emitting layer, one second light emitting layer, and one third light emitting layer are sequentially arranged in a first direction, and a closest distance between a first light emitting layer and a second light emitting layer is different from a closest distance between the second light emitting layer and a third light emitting layer, and the first direction is one of a row direction or a column direction.

14. The display substrate according to claim 9, wherein the at least one first light emitting layer is at least adjacent to two second light emitting layers, and closest distances between the at least one first light emitting layer and the adjacent two second light emitting layers are different;
or
the at least one first light emitting layer is at least adjacent to two third light emitting layers, and closest distances between the at least one first light emitting layer and the adjacent two third light emitting layers are different.

15. (canceled)

16. The display substrate according to claim 9, wherein a closest distance from a light emitting layer located in a same row as and adjacent to the at least one first light emitting layer to the at least one first light emitting layer is different from a closest distance from a light emitting layer located in a different row from and adjacent to the at least one first light emitting layer to the at least one first light emitting layer.

17. (canceled)

18. The display substrate according to claim 9, wherein the at least one first light emitting layer has a hexagonal shape, the hexagonal first light emitting layer comprises a first edge and a second edge provided oppositely in a row direction, in the row direction the first edge of the first light emitting layer is adjacent to an adjacent third light emitting layer, and the second edge of the first light emitting layer is adjacent to an adjacent second light emitting layer, and a size of the second edge in a column direction is greater than or equal to a size of the first edge in the column direction.

19. The display substrate according to claim 18, wherein at least one of the first edge and the second edge has a size of 4 microns to 9 microns in the column direction.

20. The display substrate according to claim 18, wherein a rhombus in which the hexagonal first light emitting layer is located comprises a first included angle and a second included angle which are oppositely provided in the row direction, in the row direction the first included angle is located on a side of the first edge away from the second edge, and the second included angle is located on a side of the second edge away from the first edge, and a distance between a vertex of the second included angle and the second edge is greater than or equal to a distance between a vertex of the first included angle and the first edge;
wherein in the row direction, a closest distance between at least one edge of the first edge and the second edge and a vertex of an included angle adjacent to the edge is 3 microns to 6 microns.

21-22. (canceled)

23. The display substrate according to claim 1, further comprising a drive circuit layer provided on a base substrate, wherein the drive circuit layer comprises a plurality of circuit units, the plurality of sub-pixels comprise light emitting units and circuit units, a light emitting unit is provided on a side of the drive circuit layer away from the base substrate, the light emitting unit comprises an anode and a light emitting layer; the light emitting layer is located on a side of the anode away from the drive circuit layer, a circuit unit at least comprises a pixel drive circuit, the pixel driving circuit at least comprises a storage capacitor and a compensation transistor, a first electrode of the compensation transistor is connected to a first plate of the storage capacitor through a first connection electrode; the anode of the light emitting unit is connected to the pixel drive circuit; in a row direction, an orthographic projection of an anode of at least one light emitting unit on the base substrate is not overlapped with an orthographic projection of a first connection electrode in a circuit unit, which is adjacent to the anode on at least a side, on the base substrate; in a column direction, an orthographic projection of an anode of at least one light emitting unit on the base substrate is at least partially overlapped with an orthographic projection of a first connection electrode in a circuit unit, which is adjacent to the anode on at least a side, on the base substrate.

24. The display substrate according to claim 23, wherein the plurality of light emitting units form a plurality of sub-pixel rows, a sub-pixel row comprises a plurality of light emitting units arranged sequentially in the row direction; the plurality of circuit units form a plurality of unit rows, a unit row comprises a plurality of circuit units arranged sequentially in the row direction, the plurality of sub-pixel rows comprise a plurality of first sub-pixel rows and a plurality of second sub-pixel rows, the first sub-pixel rows and the second sub-pixel rows are alternately arranged in the column direction, positions of a plurality of pixel drive circuits in one unit row correspond to positions of a plurality of light emitting units in two adjacent sub-pixel rows; in the column direction, an orthographic projection of anodes of a plurality of light emitting units in the first sub-pixel row on the base substrate is at least partially overlapped with an orthographic projection of a first connection electrode in an adjacent unit row on the base substrate, and an orthographic projection of anodes of a plurality of light emitting units in the second sub-pixel row on the base substrate is at least partially overlapped with an orthographic projection of a first connection electrode in a corresponding unit row on the base substrate;
wherein an anode of at least one light emitting unit located in the first sub-pixel row comprises an anode main body part, an anode connection part, and an anode compensation part, the anode connection part is configured to be connected to the pixel drive circuit, and the anode compensation part is provided on a side of the anode connection part away from the anode main body part.

25. (canceled)

26. The display substrate according to claim 24, wherein the first connection electrode comprises an electrode main body part and an electrode compensation part, the electrode main body part comprises a first end connected to a first plate of the storage capacitor and a second end connected to a first electrode of the compensation transistor, and the electrode compensation part is provided on a side of the first end away from the second end;
in at least one circuit unit, an orthographic projection of the anode compensation part on the base substrate is at least partially overlapped with an orthographic projection of the electrode compensation part of the first connection electrode on the base substrate; in at least one circuit unit, the orthographic projection of the anode compensation part on the base substrate is at least partially overlapped with an orthographic projection of the electrode main body part of the first connection electrode on the base substrate;
or
in at least one light emitting unit located in a first sub-pixel row, an orthographic projection of the anode main body part on the base substrate is not overlapped with an orthographic projection of the first connection electrode on the base substrate; in at least one light emitting unit located in a second sub-pixel row, an orthographic projection of an anode main body part on the base substrate is at least partially overlapped with an orthographic projection of a first connection electrode on the base substrate; in at least one light emitting unit located in a first sub-pixel row, an orthographic projection of the anode compensation part on the base substrate is at least partially overlapped with an orthographic projection of a first connection electrode in an adjacent unit row on the base substrate;
or
the anode further comprises a protrusion part, the protrusion part is provided on a side of the anode main body part away from the anode connection part, and an orthographic projection of the protrusion part of at least one anode in at least one sub-pixel row on the base substrate is at least partially overlapped with orthographic projections of a plurality of first connection electrodes in a corresponding unit row on the base substrate, respectively.

27-28. (canceled)

29. The display substrate according to claim 24, wherein the plurality of sub-pixel columns comprise a plurality of first sub-pixel columns and a plurality of second sub-pixel columns, the first sub-pixel columns and the second sub-pixel columns are alternately arranged in the row direction, a plurality of light emitting units in a first sub-pixel column are located in a first sub-pixel row, and a plurality of light emitting units in a second sub-pixel column are located in a second sub-pixel row;
the storage capacitor comprises a first plate and a second plate, the second plate is provided with an opening, positions of a plurality of light emitting units of a sub-pixel column correspond to positions of a plurality of circuit units of a unit column, the plurality of unit columns comprise a plurality of first unit columns and a plurality of second unit columns, the first unit columns and the second unit columns are alternately arranged in the row direction, orthographic projections of anode compensation parts of a plurality of light emitting units in a first sub-pixel column on the base substrate are at least partially overlapped with orthographic projections of openings on second plates of a plurality of circuit units in a corresponding first unit column on the base substrate, respectively, and the orthographic projections of the anode compensation parts of the plurality of light emitting units in the first sub-pixel column on the base substrate are at least partially overlapped with orthographic projections of first connection electrodes of the plurality of circuit units in the corresponding first unit column on the base substrate, respectively.

30. A display apparatus, comprising a display substrate according to claim 1.
